(19) United States
(12) Patent Application Publication
(10) Pub. No.: US 2024/0146024 A1
(43) Pub. Date: May 2, 2024

(54) SURFACE EMITTING LASER, LIGHT SOURCE DEVICE, ELECTRONIC DEVICE, AND METHOD FOR MANUFACTURING SURFACE EMITTING LASER

(71) Applicant: SONY SEMICONDUCTOR SOLUTIONS CORPORATION, Kanagawa (JP)

(72) Inventors: Shinichi AGATUMA, Kumamoto (JP); Masato OGAWA, Kumamoto (JP)

(21) Appl. No.: 18/279,334

(22) PCT Filed: Jan. 14, 2022
(86) PCT No.: PCT/JP2022/001116

§ 371 Date: Aug. 29, 2023

(30) Foreign Application Priority Data
Mar. 23, 2021 (JP) 2021-048525

(51) Int. Cl. H01S 5/183; G01S 17/89; H01S 5/02253; H01S 5/20

(52) U.S. Cl. CPC H01S 5/18311; G01S 17/89; H01S 5/02253; H01S 5/18347; H01S 5/2086

(57) ABSTRACT

There is provided a surface emitting laser capable of making a confinement effect of light and current different between at least two mesa structures, and capable of improving productivity.

The present technology provides a surface emitting laser including a plurality of light emitting units having a mesa structure, the light emitting units each including a first multilayer film reflector, a second multilayer film reflector, an active layer disposed between the first and second multilayer film reflectors, at least one oxide confinement layer disposed between a surface of the first multilayer film reflector on a side opposite to a surface on a side of the active layer and the active layer and/or between a surface of the second multilayer film reflector on a side opposite to a surface on a side of the active layer and the active layer, in which the mesa structures of the plurality of light emitting units include first and second mesa structures having different height dimensions, and having different numbers of the oxide confinement layers and/or different numbers of the active layers.

### TECHNICAL FIELD

The technology according to the present disclosure (hereinafter also referred to as “the present technology”) relates to a surface emitting laser, a light source device, an electronic device, and a method for manufacturing the surface emitting laser.

### BACKGROUND ART

Conventionally, a surface emitting laser including a plurality of light emitting units having a mesa structure including an oxide confinement layer is known. Some of such surface emitting lasers have different numbers of oxide confinement layers between at least two mesa structures (see, for example, Patent Document 1). In this surface emitting laser, a confinement effect of light and current can be made different between at least two mesa structures.

### CITATION LIST

### Patent Document

Patent Document 1: Japanese Patent Application Laid-Open No. 2019-62188

### SUMMARY OF THE INVENTION

### Problems to be Solved by the Invention

However, the conventional surface emitting laser has room for improvement in productivity.

Therefore, a main object of the present technology is to provide a surface emitting laser capable of making a confinement effect of light and current different between at least two mesa structures, and capable of improving productivity.

### Solutions to Problems

The present technology provides a surface emitting laser including:
a plurality of light emitting units having a mesa structure, the light emitting units each including
a first multilayer film reflector,
a second multilayer film reflector,
an active layer disposed between the first and second multilayer film reflectors,
at least one oxide confinement layer disposed between a surface of the first multilayer film reflector on a side opposite to a surface on a side of the active layer and the active layer and/or between a surface of the second multilayer film reflector on a side opposite to a surface on a side of the active layer and the active layer, in which
the mesa structures of the plurality of light emitting units include first and second mesa structures having different height dimensions, and having different numbers of the oxide confinement layers and/or different numbers of the active layers. Here, in the present description, the number of oxide confinement layers includes zero. In the present description, the number of active layers also includes zero.

The second mesa structure may have a larger height dimension and a larger number of the oxide confinement layers than the first mesa structure.

The light emitting unit having the first mesa structure may include at least one layer to be a material of the oxide confinement layer.

The second mesa structure may have the active layer, and the first mesa structure may not have the active layer.

Both the first and second mesa structures may have the active layer.

Both the first and second mesa structures may not have the active layer.

The second mesa structure may include a plurality of the oxide confinement layers on one side between the surface of the first multilayer film reflector on the side opposite to the surface on the side of the active layer and the active layer or between the surface of the second multilayer film reflector on the side opposite to the surface on the side of the active layer and the active layer, and the first mesa structure may include at least one oxide confinement layer on the one side.

The second mesa structure may include at least one of the oxide confinement layers between the surface of the first multilayer film reflector on the side opposite to the surface on the side of the active layer and the active layer and between the surface of the second multilayer film reflector on the side opposite to the surface on the side of the active layer and the active layer, and the first mesa structure may include at least one of the oxide confinement layers on one side between the surface of the first multilayer film reflector on the side opposite to the surface on the side of the active layer and the active layer or between the surface of the second multilayer film reflector on the side opposite to the surface on the side of the active layer and the active layer.

The first and second mesa structures may have the same number of oxide confinement layers, and the second mesa structure may have a larger height dimension and a larger number of the active layers than the first mesa structure.

Each of the first and second mesa structures may include at least one of the oxide confinement layers on one side between the surface of the first multilayer film reflector on the side opposite to the surface on the side of the active layer and the active layer or between the surface of the second multilayer film reflector on the side opposite to the surface on the side of the active layer and the active layer.

A dummy region may be provided between the first and second mesa structures.

An interval between the first mesa structure and the dummy region may be different from an interval between the second mesa structure and the dummy region.

The second mesa structure may have a larger height dimension than the first mesa structure, and the interval between the second mesa structure and the dummy region may be larger than the interval between the first mesa structure and the dummy region.

The second mesa structure may have a larger height dimension than the first mesa structure, and an interval between the second mesa structure and the dummy region may be equal to or less than an interval between the first mesa structure and the dummy region.

The present technology also provides a light source device including the surface emitting laser, a collimator lens disposed on a top side of a second mesa structure of the surface emitting laser, and a diffusion plate disposed on a top side of a first mesa structure of the surface emitting laser, in a case where the second mesa structure has a larger height dimension and a larger number of the oxide confinement layers than the first mesa structure.

The present technology also provides a light source device including the surface emitting laser, a collimator lens disposed on a top side of a second mesa structure of the surface emitting laser, and a diffusion plate disposed on a top side of a first mesa structure of the surface emitting laser, in a case where the first and second mesa structures have the same number of oxide confinement layers, the second mesa structure has a larger height dimension than the first mesa structure, the second mesa structure has the active layer, and the first mesa structure does not have the active layer.

The present technology also provides an electronic device including the surface emitting laser.

The electronic device may be a distance measuring device.

The present invention also provides a method for manufacturing a surface emitting laser, the method including:
layering a first multilayer film reflector, at least one active layer, a plurality of selected oxide layers, and a second multilayer film reflector on a substrate to form a multilayer body;
etching the multilayer body to form a plurality of mesas including first and second mesas having different height dimensions and different numbers of the selected oxide layers; and
selectively oxidizing the selected oxide layer of the plurality of mesas from a side surface.

The present invention also provides a method for manufacturing a surface emitting laser, the method including:
layering a first multilayer film reflector, at least one active layer, at least one selected oxide layer, and a second multilayer film reflector on a substrate to form a multilayer body;
etching the multilayer body to form a plurality of mesas including first and second mesas having different height dimensions and different numbers of the active layers; and
selectively oxidizing the selected oxide layer of the plurality of mesas from a side surface.

### BRIEF DESCRIPTION OF DRAWINGS

FIG. 1 is a cross-sectional view of a part of a surface emitting laser according to a first embodiment of the present technology.

FIG. 2 is a plan view of a surface emitting laser according to the first embodiment of the present technology.

FIG. 3 is a flowchart for describing a method for manufacturing the surface emitting laser according to the first embodiment of the present technology.

FIG. 4 is a cross-sectional view illustrating a first step of the method for manufacturing the surface emitting laser according to the first embodiment of the present technology.

FIG. 5 is a cross-sectional view illustrating a second step of the method for manufacturing the surface emitting laser according to the first embodiment of the present technology.

FIG. 6 is a cross-sectional view illustrating a third step of the method for manufacturing the surface emitting laser according to the first embodiment of the present technology.

FIG. 7 is a cross-sectional view illustrating a fourth step of the method for manufacturing the surface emitting laser according to the first embodiment of the present technology.

FIG. 8 is a cross-sectional view illustrating a fifth step of the method for manufacturing the surface emitting laser according to the first embodiment of the present technology.

FIG. 9 is a cross-sectional view illustrating a sixth step of the method for manufacturing the surface emitting laser according to the first embodiment of the present technology.

FIG. 10 is a cross-sectional view illustrating a seventh step of the method for manufacturing the surface emitting laser according to the first embodiment of the present technology.

FIG. 11 is a cross-sectional view illustrating an eighth step of the method for manufacturing the surface emitting laser according to the first embodiment of the present technology.

FIG. 12 is a cross-sectional view illustrating a ninth step of the method for manufacturing the surface emitting laser according to the first embodiment of the present technology.

FIG. 13 is a cross-sectional view illustrating a part of a surface emitting laser according to a modification of the first embodiment of the present technology.

FIG. 14 is a flowchart for describing a method for manufacturing the surface emitting laser according to the modification of the first embodiment of the present technology.

FIG. 15 is a cross-sectional view illustrating a second step of the method for manufacturing the surface emitting laser according to the modification of the first embodiment of the present technology.

FIG. 16 is a cross-sectional view illustrating a third step of the method for manufacturing the surface emitting laser according to the modification of the first embodiment of the present technology.

FIG. 17 is a cross-sectional view illustrating a fourth step of the method for manufacturing the surface emitting laser according to the modification of the first embodiment of the present technology.

FIG. 18 is a cross-sectional view illustrating a fifth step of the method for manufacturing the surface emitting laser according to the modification of the first embodiment of the present technology.

FIG. 19 is a cross-sectional view illustrating a sixth step of the method for manufacturing the surface emitting laser according to the modification of the first embodiment of the present technology.

FIG. 20 is a cross-sectional view illustrating a seventh step of the method for manufacturing the surface emitting laser according to the modification of the first embodiment of the present technology.

FIG. 21 is a cross-sectional view illustrating an eighth step of the method for manufacturing the surface emitting laser according to the modification of the first embodiment of the present technology.

FIG. 22 is a cross-sectional view illustrating a ninth step of the method for manufacturing the surface emitting laser according to the modification of the first embodiment of the present technology.

FIG. 23 is a cross-sectional view illustrating a tenth step of the method for manufacturing the surface emitting laser according to the modification of the first embodiment of the present technology.

FIG. 24 is a cross-sectional view illustrating an eleventh step of the method for manufacturing the surface emitting laser according to the modification of the first embodiment of the present technology.

FIG. 25 is a cross-sectional view illustrating a twelfth step of the method for manufacturing the surface emitting laser according to the modification of the first embodiment of the present technology.

FIG. 26 is a cross-sectional view of a part of a surface emitting laser according to a second embodiment of the present technology.

FIG. 27 is a cross-sectional view of a part of a surface emitting laser according to a third embodiment of the present technology.

FIG. 28 is a cross-sectional view of a part of a surface emitting laser according to a fourth embodiment of the present technology.

FIG. 29 is a cross-sectional view of a part of a surface emitting laser according to a fifth embodiment of the present technology.

FIG. 30 is a cross-sectional view of a part of a surface emitting laser according to a sixth embodiment of the present technology.

FIG. 31 is a plan view of a surface emitting laser according to a modification of the present technology.

FIG. 32 is a diagram illustrating an application example of the surface emitting laser according to the first embodiment of the present technology to a distance measuring device.

FIG. 33 is a cross-sectional view illustrating a configuration of a light source device including the surface emitting laser according to the first embodiment of the present technology.

FIG. 34 is a block diagram illustrating an example of a schematic configuration of a vehicle control system.

FIG. 35 is an explanatory view illustrating an example of an installation position of the distance measuring device.

### MODE FOR CARRYING OUT THE INVENTION

Hereinafter, preferred embodiments of the present technology will be described in detail with reference to the accompanying drawings. Note that in the description and the drawings, components having substantially the same function and configuration are denoted by the same reference numerals, and redundant descriptions are omitted. The embodiments described below illustrate representative embodiments of the present technology, and the scope of the present technology is not to be narrowly interpreted according to these embodiments. In the present description, even in a case where it is described that each of a surface emitting laser, a light source device, an electronic device, and a method for manufacturing the surface emitting laser according to the present technology exhibits a plurality of effects, it is sufficient if each of the surface emitting laser, the light source device, the electronic device, and the method for manufacturing a surface emitting laser according to the present technology exhibits at least one effect. The effects described herein are merely examples and are not limited, and other effects may be provided.

Furthermore, the description will be given in the following order.
1. Surface emitting laser according to first embodiment of present technology
2. Surface emitting laser according to modification of first embodiment of present technology
3. Surface emitting laser according to second embodiment of present technology
4. Surface emitting laser according to third embodiment of present technology
5. Surface emitting laser according to fourth embodiment of present technology
6. Surface emitting laser according to fifth embodiment of present technology
7. Surface emitting laser according to sixth embodiment of present technology
8. Modification of present technology
9. Application example to electronic device
10. Example in which surface emitting laser is applied to distance measuring device
11. Example in which distance measuring device is mounted on mobile body

<1. Surface Emitting Laser According to First Embodiment of Present Technology>

Hereinafter, a surface emitting laser 10 according to a first embodiment of the present technology will be described with reference to the drawings.

(Overall Configuration)

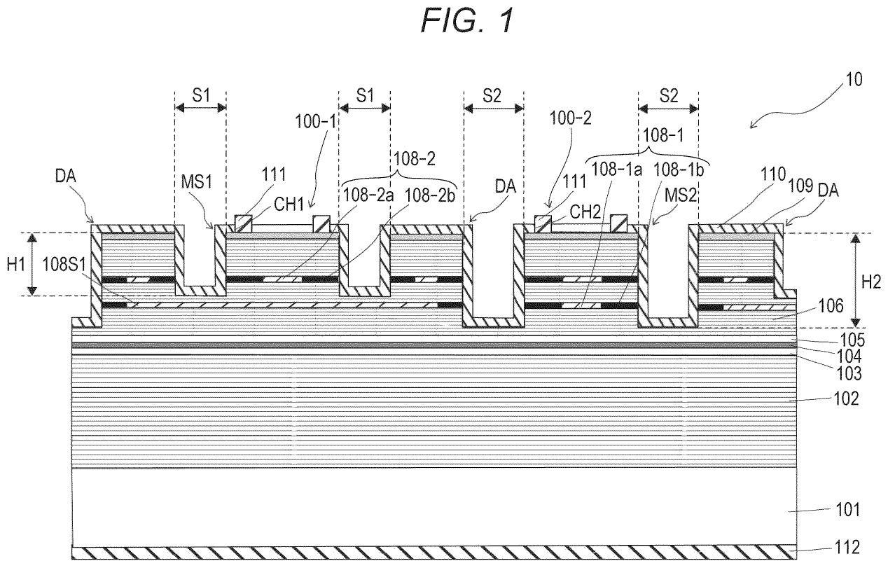

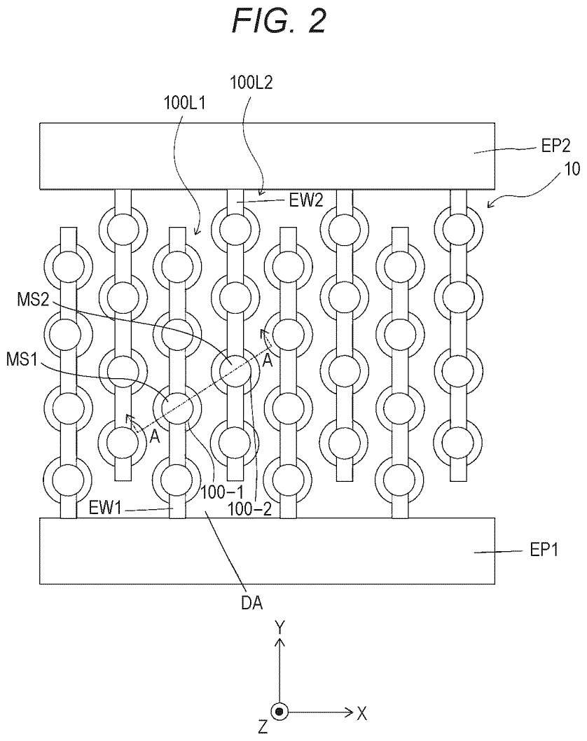

FIG. 1 is a cross-sectional view (cross-sectional view taken along line A-A in FIG. 2) of a part of the surface emitting laser 10 according to the first embodiment of the present technology. FIG. 2 is a plan view of the surface emitting laser 10 according to the first embodiment of the present technology.

Hereinafter, the description will be given using an XYZ three-dimensional orthogonal coordinate system illustrated in FIG. 2 and the like as appropriate. Moreover, in the following description, in the cross-sectional view of FIG. 1 and the like, a direction corresponding to a +Z direction of FIG. 2 and the like is defined as an upward direction, and a direction corresponding to a −Z direction is defined as a downward direction.

As illustrated in FIG. 1, the surface emitting laser 10 has a layered structure in which a first multilayer film reflector 102, a first cladding layer 103, an active layer 104, a second cladding layer 105, a second multilayer film reflector 106 including at least one oxide confinement layer therein, and a contact layer 109 are layered in this order on a substrate 101. A layering direction in the layered structure coincides with a Z-axis direction in FIG. 2 and the like.

As an example, the surface emitting laser 10 is a surface emitting vertical cavity surface emitting laser (VCSEL) that emits light from a front surface (upper surface) side opposite to a back surface (lower surface) side of the substrate 101.

The surface emitting laser 10 includes a plurality of light emitting units having a mesa structure.

As an example, the plurality of light emitting units includes a plurality of first light emitting units 100-1 having a first mesa structure MS1 and a plurality of second light emitting units 100-2 having a second mesa structure MS2.

The surface emitting laser 10 further has, as an example, a dummy region DA (non-light emitting region) between the first and second mesa structures MS1 and MS2.

In the surface emitting laser 10, each of the first light emitting units 100-1, each of the second light emitting units 100-2, and each of the dummy regions DA are located at different positions in an in-plane direction. Here, each of the dummy regions DA exists around the corresponding first and second light emitting units 100-1 and 100-2, and are integrated as a whole (see FIG. 2).

As an example, each of the second light emitting units 100-2 includes a first multilayer film reflector 102, a second multilayer film reflector 106, an active layer 104 disposed between the first and second multilayer film reflectors 102 and 106, and first and second oxide confinement layers 108-1 and 108-2 disposed between a surface of the second multilayer film reflector 106 on a side opposite to a surface on the active layer 104 side and the active layer 104. Here, the second oxide confinement layer 108-2 is located above the first oxide confinement layer 108-1.

As an example, the second mesa structure MS2 of each of the second light emitting units 100-2 includes an upper portion more than half (portion excluding a bottom portion) of the second multilayer film reflector 106, the first and second oxide confinement layers 108-1 and 108-2, and the contact layer 109.

Each of the first light emitting units 100-1 includes the first multilayer film reflector 102, the second multilayer film reflector 106, the active layer 104 disposed between the first and second multilayer film reflectors 102 and 106, and a selected oxide layer 108S1 and the second oxide confinement layer 108-2 disposed between a surface of the second multilayer film reflector 106 on the side opposite to the surface on the active layer 104 side and the active layer 104. The selected oxide layer 108S1 is a layer to be a material of the first oxide confinement layer 108-1. The selected oxide layer 10851 is at substantially the same position as the first oxide confinement layer 108-1 in the layering direction (Z-axis direction).

As an example, the first mesa structure MS1 of each of the first light emitting units 100-1 includes an upper half portion (portion excluding a lower half portion) of the second multilayer film reflector 106, the second oxide confinement layer 108-2, and the contact layer 109.

As can be seen from the above description, the first mesa structure MS1 and the second mesa structure MS2 have different numbers of oxide confinement layers. The second mesa structure MS2 has two oxide confinement layers between the active layer 104 and the surface of the second multilayer film reflector 106 on the side opposite to the surface on the active layer 104 side, and the first mesa structure MS1 has one oxide confinement layer between the surface of the second multilayer film reflector 106 on the side opposite to the surface on the active layer 104 side and the active layer 104.

Height dimensions of the first and second mesa structures MS1 and MS2 are different from each other. More specifically, a height dimension H2 of the second mesa structure MS2 is larger than a height dimension H1 of the first mesa structure MS1. Here, the height dimension of the mesa structure means a distance from a bottom surface to an upper surface of the mesa structure.

More specifically, as an example, a bottom surface of the second mesa structure MS2 is located below a bottom surface of the first mesa structure MS1. Upper surfaces of the first and second mesa structures MS1 and MS2 are, for example, an upper surface of the contact layer 109. Consequently, H2>H1.

As an example, the bottom surfaces of the first and second mesa structures MS1 and MS2 are all located in the second multilayer film reflector 106. That is, as an example, neither of the first and second mesa structures MS1 and MS2 has the active layer 104.

As an example, the bottom surface of the first mesa structure MS1 is located between the selected oxide layer 108S1 and the second oxide confinement layer 108-2 in the second multilayer film reflector 106.

As an example, the bottom surface of the second mesa structure MS2 is located between the second cladding layer 105 and the first oxide confinement layer 108-1 in the second multilayer film reflector 106.

Each dummy region DA includes the upper portion more than half (portion excluding the bottom portion) of the second multilayer film reflector 106, and the selected oxide layer 108S1 and the second oxide confinement layer 108-2 disposed between the surface of the second multilayer film reflector 106 on the side opposite to the surface on the active layer 104 side and the active layer 104.

A height dimension of the dummy region DA between the first and second mesa structures MS1 and MS2 on the first mesa structure MS1 side is H1, and a height dimension of the dummy region DA on the second mesa structure MS2 side is H2. That is, the dummy region DA has a function of adjusting a difference in height dimension (H2−H1) between the first and second mesa structures MS1 and MS2.

The interval between each of the first and second mesa structures MS1 and MS2 and the dummy region DA between the first and second mesa structures MS1 and MS2 is different from each other. More specifically, an interval S2 between the second mesa structure MS2 and the dummy region DA adjacent to each other is larger than an interval S1 between the first mesa structure MS1 and the dummy region DA adjacent to each other.

(Substrate)

As an example, the substrate 101 is a GaAs substrate (for example, an n-GaAs substrate) of a first conductivity type (for example, n-side).

(First Multilayer Film Reflector)

The first multilayer film reflector 102 is, as an example, a semiconductor multilayer film reflector of the first conductivity type (for example, n-type), and has a structure in which a plurality of types (for example, two types) of semiconductor layers (refractive index layers) having mutually different refractive indexes is alternately layered with an optical thickness of ¼ ( 2/4) of an oscillation wavelength 2. As an example, each refractive index layer of the first multilayer film reflector 102 is formed by an AlGaAs-based compound semiconductor (for example, n-AlGaAs) of the first conductivity type (for example, n-type).

As an example, a cathode electrode 112 (n-side electrode) is provided on the back surface (lower surface) of the substrate 101. The cathode electrode 112 may have a single layer structure or a layered structure.

The cathode electrode 112 contains, for example, at least one type of metal (including an alloy) selected from a group including Au, Ag, Pd, Pt, Ni, Ti, V, W, Cr, Al, Cu, Zn, Sn, and In.

(First Cladding Layer)

The first cladding layer 103 is formed by an AlGaAs-based compound semiconductor (n-AlGaAs) of the first conductivity type (for example, n-type). The “cladding layer” is also referred to as a “spacer layer”.

(Active Layer)

The active layer 104 has a quantum well structure including a barrier layer including, for example, an AlGaAs-based compound semiconductor, and a quantum well layer. This quantum well structure may be a single quantum well structure (QW structure) or a multiple quantum well structure (MQW structure).

The active layer 104 constitutes a resonator together with the first and second cladding layers 103 and 105.

(Second Cladding Layer)

The second cladding layer 105 is formed by an AlGaAs-based compound semiconductor (p-AlGaAs) of a second conductivity type (for example, p-type). The “cladding layer” is also referred to as a “spacer layer”.

(Second Multilayer Film Reflector)

The second multilayer film reflector 106 is, as an example, a semiconductor multilayer film reflector of the second conductivity type (for example, p-type), and has a structure in which a plurality of types (for example, two types) of semiconductor layers (refractive index layers) having mutually different refractive indexes is alternately layered with an optical thickness of ¼ wavelength of the oscillation wavelength. Each refractive index layer of the second multilayer film reflector 106 is formed by an AlGaAs-based compound semiconductor of the second conductivity type (for example, p-type). The reflectance of the second multilayer film reflector 106 is slightly lower than the reflectance of the first multilayer film reflector 102.

(Oxide Confinement Layer)

The second oxide confinement layer 108-2 is disposed inside the second multilayer film reflector 106 of the first mesa structure MS1.

The first and second oxide confinement layers 108-1 and 108-2 are disposed inside the second multilayer film reflector 106 of the second mesa structure MS2. The second oxide confinement layer 108-2 is disposed above the first oxide confinement layer 108-1.

As an example, the first oxide confinement layer 108-1 includes a non-oxidized region 108-1a formed by AlAs and an oxidized region 108-1b formed by an oxide of AlAs (for example, Al₂O₃) surrounding the non-oxidized region. The non-oxidized region 108-1a is a current/light passage region, and the oxidized region 108-1b is a current/light confinement region.

As an example, the second oxide confinement layer 108-2 includes a non-oxidized region 108-2a formed by AlAs and an oxidized region 108-2b formed by an oxide of AlAs (for example, Al₂O₃) surrounding the non-oxidized region. The non-oxidized region 108-2a is a current/light passage region, and the oxidized region 108-2b is a current/light confinement region.

(Contact Layer)

The contact layer 109 is formed by, for example, a GaAs-based compound semiconductor (for example, p-GaAs) of the second conductivity type (for example, p-type).

Here, the surface emitting laser 10 is covered with an insulating film 110 except for central portions of tops of the first and second mesa structures MS1 and MS2. The insulating film 110 is formed by, for example, SiO₂, SiN, SiON, or the like.

A contact hole CH1 for electrode extraction is formed in the insulating film 110 covering the top of each of the first mesa structures MS1. In the contact hole CH1, an anode electrode 111 having a circling shape (for example, a ring shape) is disposed so as to be in contact with the second contact layer 109 of the first mesa structure MS1. A region inside the anode electrode 111 in the contact hole CH1 is an emission port of the first light emitting unit 100-1.

A contact hole CH2 for electrode extraction is formed in the insulating film 110 covering the top of each of the second mesa structures MS2. In the contact hole CH2, the anode electrode 111 having a circling shape (for example, a ring shape) is disposed so as to be in contact with the second contact layer 109 of the second mesa structure MS2. A region inside the anode electrode 111 in the contact hole CH2 is an emission port of the second light emitting unit 100-2.

The anode electrode 111 may have a single layer structure or a layered structure.

The anode electrode 111 contains, for example, at least one type of metal (including an alloy) selected from a group including Au, Ag, Pd, Pt, Ni, Ti, V, W, Cr, Al, Cu, Zn, Sn, and In.

In the surface emitting laser 10, as an example, as illustrated in FIG. 2, a first light emitting unit row 100L1 including a plurality of first light emitting units 100-1 arranged in the Y-axis direction and a second light emitting unit row 100L2 including a plurality of second light emitting units 100-2 arranged in the Y-axis direction are alternately arranged in an X-axis direction in a state of being shifted in the Y-axis direction. That is, in the surface emitting laser 10, a plurality of light emitting units is arranged in a staggered manner as a whole. Here, the emission direction of each light emitting unit is the +Z direction.

The anode electrodes 111 of the plurality of first light emitting units 100-1 of each first light emitting unit row 100L1 are connected to each other via a common first electrode wiring EW1 (anode wiring). Each of the first electrode wirings EW1 is connected to a first electrode pad EP1. The first electrode pad EP1 is connected to a first terminal (+terminal) of a laser driver. The first electrode wiring EW1 is formed by, for example, Au.

The anode electrodes 111 of the plurality of second light emitting units 100-2 of each second light emitting unit row 100L2 are connected to each other via a second electrode wiring EW2 (anode wiring line). Each of the second electrode wirings EW2 is connected to a second electrode pad EP2. The second electrode pad EP2 is connected to a second terminal (+terminal) of the laser driver. The second electrode wiring EW2 is formed by, for example, Au.

The cathode electrode 112 of each light emitting unit is a common electrode, and is connected to a third terminal (−terminal) of the laser driver.

The laser driver can independently apply a voltage between the first and third terminals and between the second and third terminals. That is, either the first light emitting unit row group including the plurality of first light emitting unit rows 100L1 or the second light emitting unit row group including the plurality of second light emitting unit rows 100L2 can be selectively driven by the laser driver.

Here, in the second mesa structure MS2 having two oxide confinement layers, since an equivalent refractive index difference Δn between the non-oxidized region and the oxidized region is relatively large, generation of a higher mode (multimode) is suppressed, and a single mode is easily obtained. Thus, the second light emitting unit 100-2 having the second mesa structure MS2 is suitable for generating spot light.

On the other hand, in the first mesa structure MS1 having one oxide confinement layer, since the equivalent refractive index difference Δn between the non-oxidized region and the oxidized region is relatively small, the higher mode (multimode) is easily obtained. Therefore, the first light emitting unit 100-1 having the first mesa structure MS1 is suitable for generating diffused light.

(Operation of Surface Emitting Laser)

Hereinafter, the operation of the surface emitting laser 10 will be described with reference to FIGS. 1 and 2.

In the surface emitting laser 10, a current injected from the first terminal of the laser driver to the anode electrode 111 of each of the first light emitting units 100-1 via the first electrode pad EP1 passes through the contact layer 109 and an upper portion of the second multilayer film reflector 106, is confined by the second oxide confinement layer 108-2, and is injected into the active layer 104 via a lower portion of the second multilayer film reflector 106 and the second cladding layer 105. At this time, the active layer 104 emits light, and the light is confined between the first and second multilayer film reflectors 102 and 106 by the second oxide confinement layer 108-2 and reciprocates while being amplified by the active layer 104, and when oscillation conditions are satisfied, laser oscillation in which the multimode is dominant occurs, and laser light is emitted from the emission port of the first light emitting unit 100-1. The current that has passed through the active layer 104 reaches the cathode electrode 112 via the first cladding layer 103, the first multilayer film reflector 102, and the substrate 101, and flows out from the cathode electrode 112 to the third terminal of the laser driver.

In the surface emitting laser 10, the current injected from the second terminal of the laser driver to the anode electrode 111 of the second light emitting unit 100-2 via the second electrode pad EP2 passes through the contact layer 109 and the upper portion of the second multilayer film reflector 106, is confined by the second oxide confinement layer 108-2, passes through the middle portion of the second multilayer film reflector 106, is confined by the first oxide confinement layer 108-1, and then is injected into the active layer 104 via the lower portion of the second multilayer film reflector 106 and the second cladding layer 105. At this time, the active layer 104 emits light, the light is confined between the first and second multilayer film reflectors 102 and 106 by the first and second oxide confinement layers 108-1 and 108-2 and reciprocates while being amplified by the active layer 104, and when the oscillation conditions are satisfied, laser oscillation in which the single mode is dominant occurs, and laser light is emitted from the emission port of the second light emitting unit 100-2. The current that has passed through the active layer 104 reaches the cathode electrode 112 via the first cladding layer 103, the first multilayer film reflector 102, and the substrate 101, and flows out from the cathode electrode 112 to the third terminal of the laser driver.

(Method for Manufacturing Surface Emitting Laser)

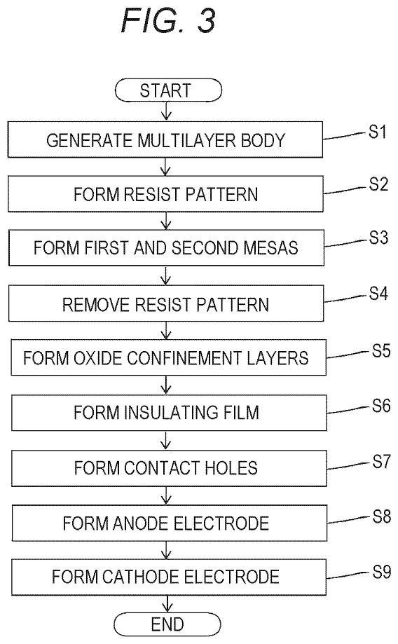

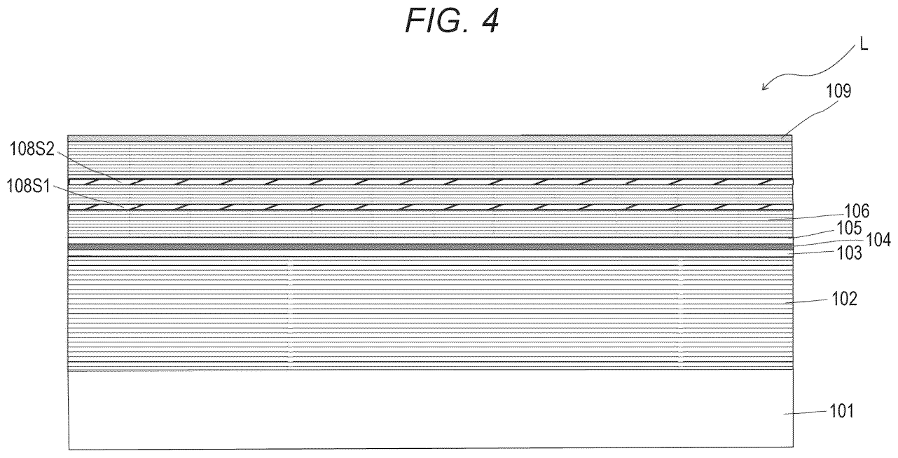

Hereinafter, a method for manufacturing the surface emitting laser 10 will be described with reference to a flowchart of FIG. 3 and cross-sectional views (process diagrams) of FIGS. 4 to 12.

Here, as an example, a plurality of surface emitting lasers 10 is simultaneously generated on one wafer which is a base material of the substrate 101 by a semiconductor manufacturing method using a semiconductor manufacturing apparatus, and then a series of the plurality of integrated surface emitting lasers 10 is separated from each other by dicing to obtain a plurality of chip-shaped surface emitting lasers 10.

In the first step S1, a multilayer body L is generated. Specifically, using a chemical vapor deposition (CVD) method, for example, a metal organic chemical vapor deposition (MOCVD) method, as illustrated in FIG. 4, the first multilayer film reflector 102, the first cladding layer 103, the active layer 104, the second cladding layer 105, the second multilayer film reflector 106 including the selected oxide layers 108S1 and 108S2 therein, and the contact layer 109 are layered in this order on the substrate 101 to generate the multilayer body L.

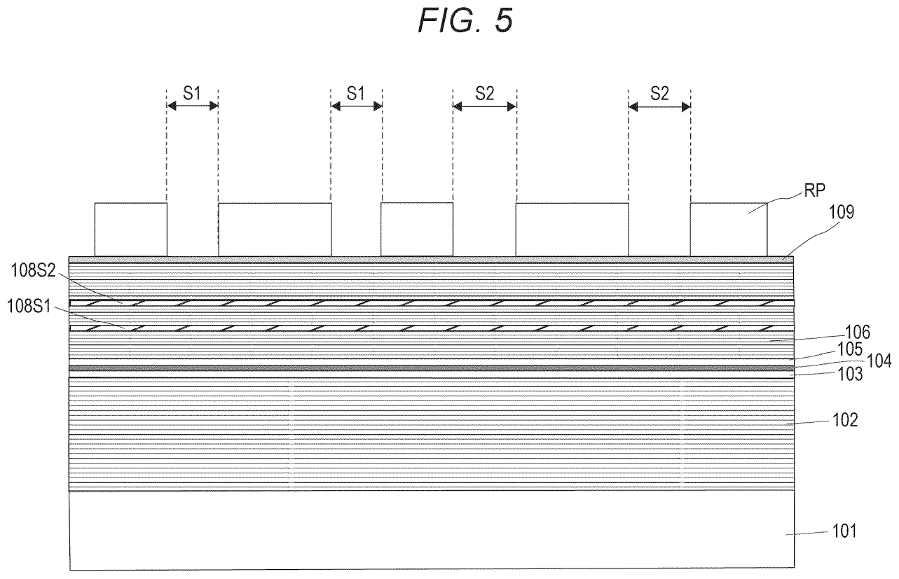

In the next step S2, a resist pattern RP is formed. Specifically, as illustrated in FIG. 5, a resist pattern RP for forming the first and second mesa structures MS1 and MS2 and the dummy region DA is formed on the multilayer body. In the resist pattern RP, an interval between a portion for forming the first mesa structure MS1 and a portion for forming the dummy region DA adjacent to the first mesa structure MS1 is S1, and an interval between a portion for forming the second mesa structure MS2 and a portion for forming the dummy region DA adjacent to the second mesa structure MS2 is S2 (>S1).

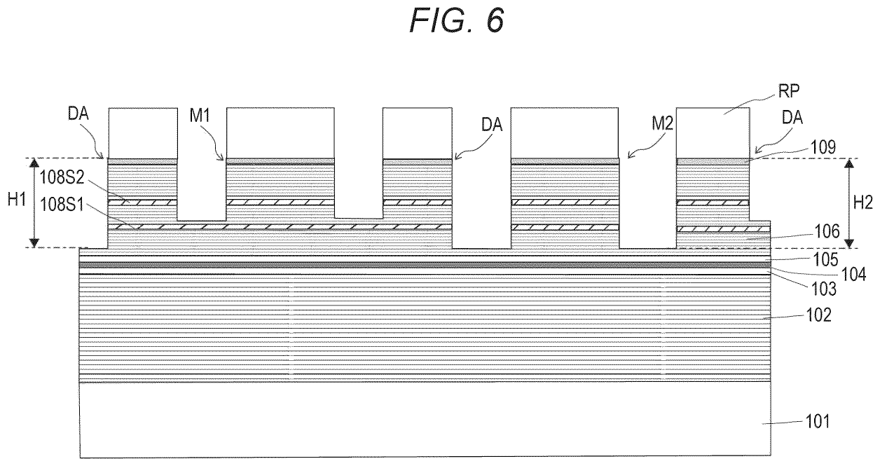

In the next step S3, the first and second mesas M1 and M2 are formed. Specifically, as illustrated in FIG. 6, the multilayer body is dry-etched or wet-etched using the resist pattern RP as a mask to form a first mesa M1 to be the first mesa structure MS1 and a second mesa M2 to be the second mesa structure MS2. Here, etching is performed using a microloading effect so that the bottom surface of the first mesa M1 (an etching bottom surface for forming the first mesa M1) is positioned between the selected oxide layer 108S1 and the selected oxide layer 108S2 in the second multilayer film reflector 106, and the bottom surface of the second mesa M2 (an etching bottom surface for forming the second mesa M2) is positioned between the second cladding layer 105 and the selected oxide layer 108S2 in the second multilayer film reflector 106. As a result, the first mesa M1 having the height dimension H1, the second mesa 2 having the height dimension H2 (>H1), and the dummy region DA are formed.

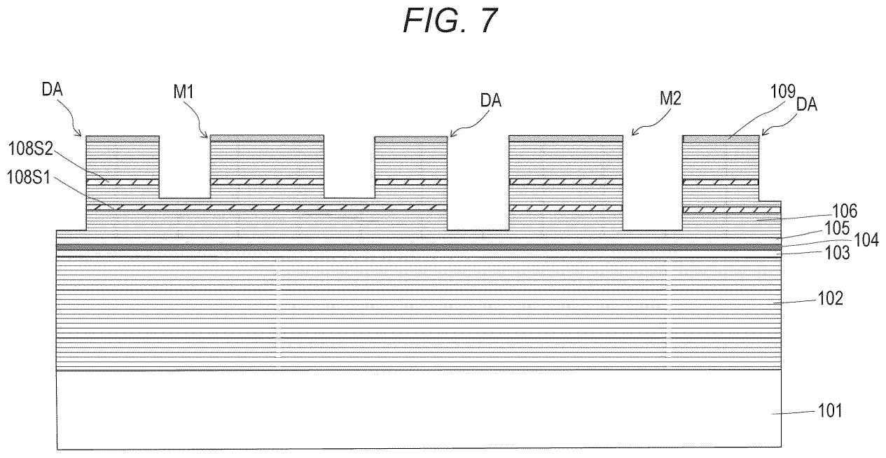

In the next step S4, the resist pattern RP is removed (see FIG. 7).

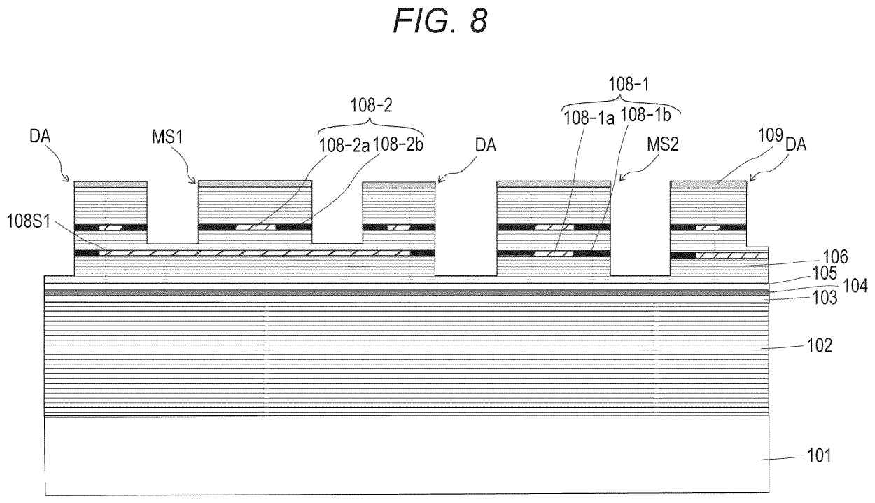

In the next step S5, oxide confinement layers are formed. Specifically, as illustrated in FIG. 8, peripheral portions of the selected oxide layer 108S2 (see FIG. 7) of the first mesa M1 and the selected oxide layers 108S1 and 108S2 (see FIG. 7) of the second mesa M2 are oxidized to form the first and second oxide confinement layers 108-1 and 108-2. More specifically, the first and second mesas M1 and M2 are exposed to a water vapor atmosphere, and the selected oxide layers 108S1 and 108S2 are oxidized (selectively oxidized) from the side surfaces to form the first and second oxide confinement layers 108-1 and 108-2 in which the periphery of the non-oxidized region is surrounded by the oxidized region. At this time, the peripheral portion of the selected oxide layer 10851 on the first mesa structure MS1 side is also oxidized. As a result, the first mesa M1 becomes the first mesa structure MS1, and the second mesa M2 becomes the second mesa structure MS.

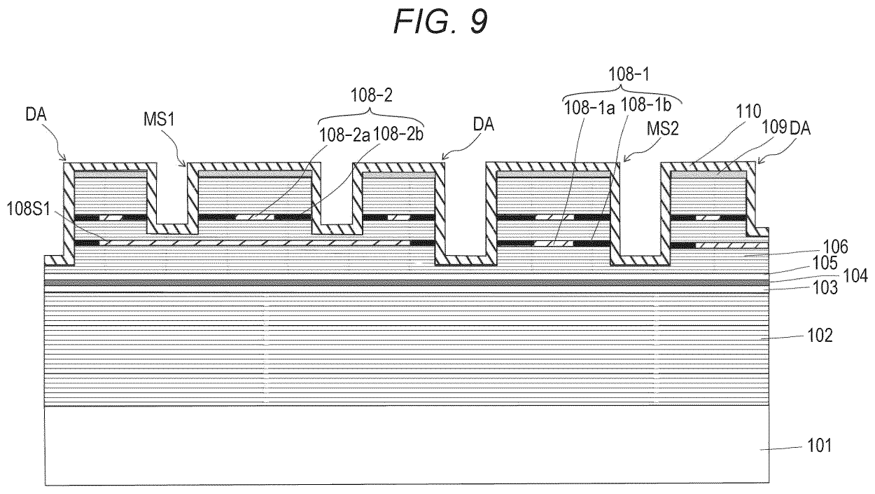

In the next step S6, the insulating film 110 is formed. Specifically, as illustrated in FIG. 9, the insulating film 110 is formed on the multilayer body in which the first and second mesa structures MS1 and MS2 and the dummy region DA are formed.

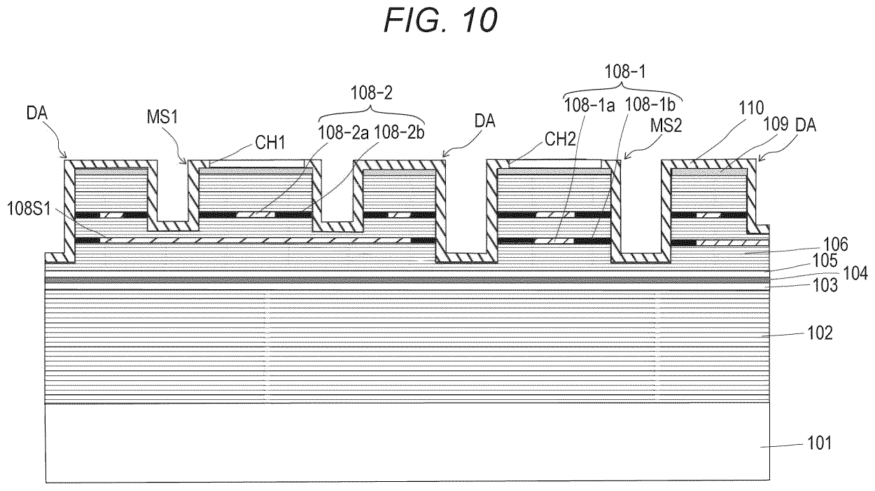

In the next step S7, the contact holes CH1 and CH2 are formed (see FIG. 10). Specifically, on the insulating film 110 of the multilayer body in which the first and second mesa structures MS1 and MS2 and the dummy region DA are formed and the insulating film 110 is formed, a resist pattern that covers a region other than the central portions of the tops of the first and second mesa structures MS1 and MS2 is generated. Next, dry etching or wet etching is performed using this resist pattern as a mask, and the insulating film 110 on the central portions of the tops of the first and second mesa structures MS1 and MS2 is removed to form the contact holes CH1 and CH2. Thus, the tops of the first and second mesa structures MS1 and MS2 are exposed.

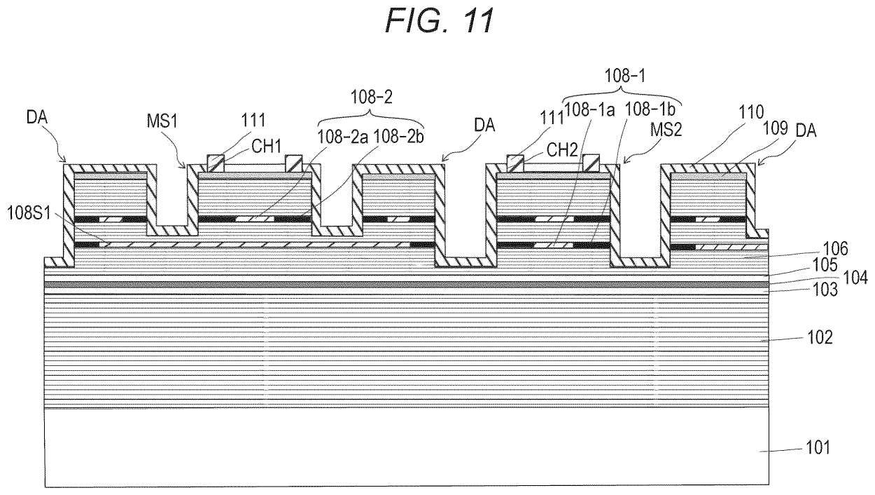

In the next step S8, the anode electrode 111 is formed (see FIG. 11). Specifically, for example, a resist is applied to a central region surrounded by a circling region where the anode electrode 111 is to be formed on the top of the first mesa structure MS1, an electrode material is formed on the top of the first mesa structure MS1 via the contact hole CH1 and an electrode material is formed on the top of the second mesa structure MS2 via the contact hole CH2 by an EB vapor deposition method, and the anode electrode 111 having a circling shape (for example, a ring shape) is formed on the top of the first and second mesa structures MS1 and MS2 by lifting off the resist and the electrode material on the resist.

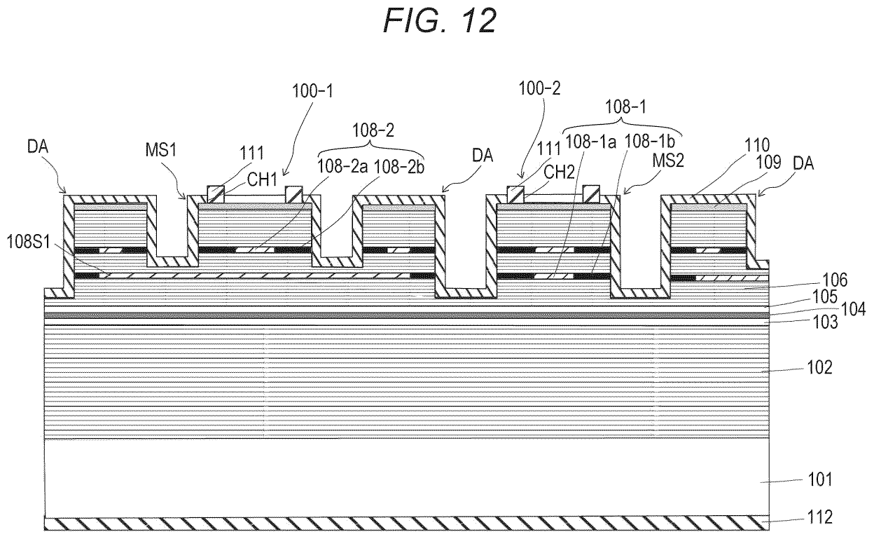

In the final step S9, the cathode electrode 112 is formed (see FIG. 12). Specifically, after the back surface of the substrate 101 is ground and thinned, an electrode material is formed on the back surface to form the cathode electrode 112.

Thereafter, post-processing such as annealing is performed, and a plurality of surface emitting lasers 10 is formed on one wafer.

Next, the electrode pads EP1 and EP2 are formed.

Next, each first electrode wiring EW1 is formed by, for example, a plating method so as to be in contact with the anode electrodes 111 of the corresponding plurality of first light emitting units 100-1 and to be in contact with the first electrode pad EP1. Moreover, each second electrode wiring EW2 is formed by, for example, a plating method so as to be in contact with the anode electrodes 111 of the corresponding plurality of second light emitting units 100-2 and to be in contact with the second electrode pad EP2. At this time, it is preferable to form a base layer (for example, nickel plating, chromium plating, or the like) to be a seed of plating by using, for example, vapor deposition, sputtering, or the like at portions of the insulating film 110 where the first and second electrode wirings EW1 and EW2 are to be formed. The first and second electrode wirings EW1 and EW2 are formed to have a thickness (for example, about 2 μm) that can sufficiently prevent a voltage drop. Thereafter, the plurality of surface emitting lasers 10 (here, the first and second electrode pads EP1 and EP2 are included) is separated from each other by dicing, and the plurality of chip-shaped surface emitting lasers 10 is obtained.

(Effects of Surface Emitting Laser and Method for Manufacturing the Same)

Hereinafter, effects of the surface emitting laser 10 and a manufacturing method thereof according to the first embodiment of the present technology will be described.

The surface emitting laser 10 according to the first embodiment includes the first multilayer film reflector 102, the second multilayer film reflector 106, the active layer 104 disposed between the first and second multilayer film reflectors 102 and 106, and at least one oxide confinement layer disposed between the surface of the second multilayer film reflector 106 on the side opposite to the surface on the active layer 104 side and the active layer 104, and includes a plurality of light emitting units having a mesa structure. The mesa structures of the plurality of light emitting units include first and second mesa structures MS1 and MS2 having different height dimensions and different numbers of oxide confinement layers.

In this case, the first and second mesa structures MS1 and MS2 can be formed by one crystal growth (for example, epitaxial growth).

Consequently, with the surface emitting laser 10 of the first embodiment, it is possible to provide a surface emitting laser capable of making a confinement effect of light and current different between at least two mesa structures, and capable of improving productivity.

On the other hand, for example, a surface emitting laser described in Patent Document 1 has at least two mesa structures having different numbers of oxide confinement layers and the same height dimension. In this surface emitting laser, at least two mesa structures cannot be formed by one crystal growth. That is, in this surface emitting laser, it is necessary to perform crystal growth every time each mesa structure is formed, and there is room for improving productivity.

The second mesa structure MS2 has a larger height dimension and a larger number of oxide confinement layers than the first mesa structure MS1. Thus, the confinement effect of light and current of the second mesa structure MS2 can be made larger than the confinement effect of light and current of the first mesa structure MS1.

The first light emitting unit 100-1 having the first mesa structure MS1 may include at least one layer to be a material of the first oxide confinement layer 108-1.

None of the first and second mesa structures MS1 and MS2 has the active layer 104. Thus, the etching depth at the time of forming the first and second mesa structures MS1 and MS2 can be made relatively shallow, and the time required for etching can be shortened.

The second mesa structure MS2 has a plurality of oxide confinement layers between the surface of the second multilayer film reflector 106 on the side opposite to the surface on the active layer 104 side and the active layer 104, and the first mesa structure MS1 has one oxide confinement layer between the surface of the second multilayer film reflector 106 on the side opposite to the surface on the active layer 104 side and the active layer 104. Thus, the above effect can be obtained by a layer configuration having a relatively small number of layers.

The surface emitting laser 10 has a dummy region DA between the first and second mesa structures MS1 and MS2. Thus, the dummy region DA can adjust a difference in height dimension between the first and second mesa structures MS1 and MS2. That is, by the dummy region DA, the first and second mesa structures MS1 and MS2 can be connected in a state where their respective height dimensions are maintained in the same layered structure.

The interval S1 between the first mesa structure MS1 and the dummy region DA is different from the interval S2 between the second mesa structure MS2 and the dummy region DA. More specifically, the second mesa structure MS2 has a larger height dimension than the first mesa structure MS1, and the interval S2 between the second mesa structure MS and the dummy region DA is larger than the interval S1 between the first mesa structure MS1 and the dummy region DA. Thus, for example, the first mesa M1 to be the first mesa structure MS1 and the second mesa M2 to be the second mesa structure MS2 can be simultaneously generated by one etching using the microloading effect.

The method for manufacturing the surface emitting laser 10 according to the first embodiment includes a step of layering the first multilayer film reflector 102, the active layer 104, the plurality of (for example, two) selected oxide layers 10851 and 108S2, and the second multilayer film reflector 106 on the substrate 101 to generate the multilayer body L, a step of etching the multilayer body L to form a plurality of mesas including first and second mesas having different height dimensions and different numbers of selected oxide layers, and a step of selectively oxidizing the selected oxide layers of the plurality of mesas from side surfaces.

In this case, the first and second mesa structures MS1 and MS2 can be formed by one crystal growth (for example, epitaxial growth).

Consequently, it is possible to efficiently manufacture a surface emitting laser capable of making the confinement effect of light and current different between at least two mesa structures.

<2. Surface Emitting Laser According to Modification of First Embodiment of Present Technology>

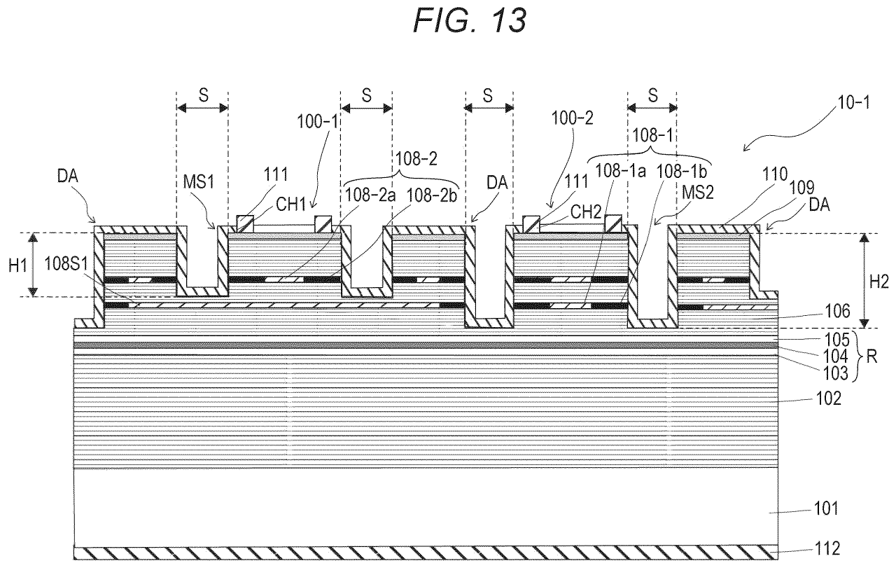

Hereinafter, a surface emitting laser 10-1 according to a modification of the first embodiment of the present technology will be described with reference to the drawings. FIG. 13 is a part (corresponding to the cross-sectional view taken along line A-A in FIG. 2) of the cross-sectional view of the surface emitting laser 10-1 of the modification.

As illustrated in FIG. 13, the surface emitting laser 10-1 of the modification has a configuration similar to that of the surface emitting laser 10 of the first embodiment except that the interval S1 between the first mesa structure MS1 and the dummy region DA adjacent to each other and the interval S2 between the second mesa structure MS2 and the dummy region DA adjacent to each other have the same size S. The surface emitting laser 10-1 has an effect similar to that of the surface emitting laser 10 of the first embodiment.

(Method for Manufacturing Surface Emitting Laser)

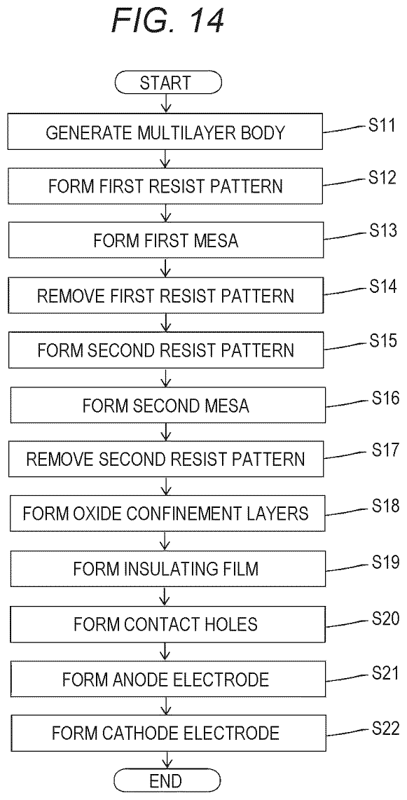

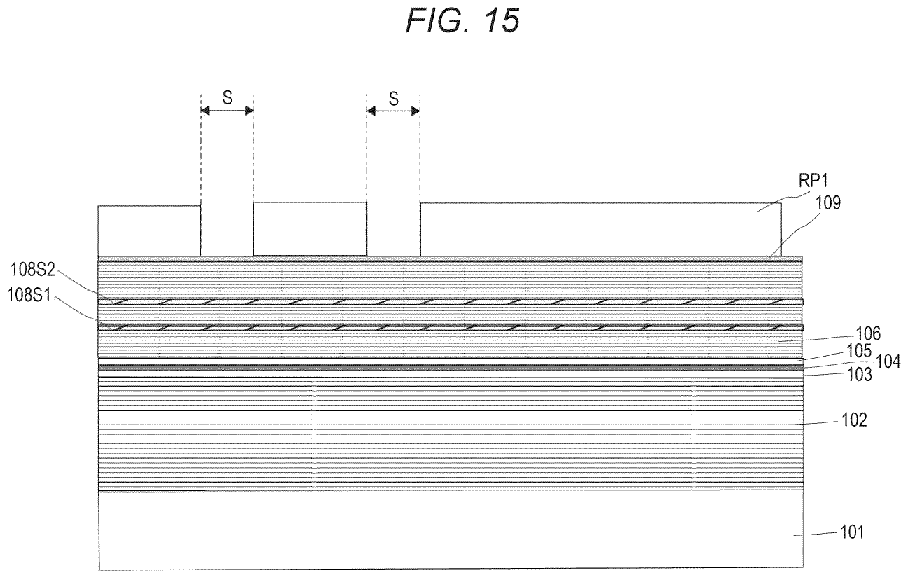

Hereinafter, a method for manufacturing the surface emitting laser 10-1 will be described with reference to a flowchart of FIG. 14 and cross-sectional views (process diagrams) of FIGS. 15 to 25.

Here, as an example, a plurality of surface emitting lasers 10-1 is simultaneously generated on one wafer which is a base material of the substrate 101 by a semiconductor manufacturing method using a semiconductor manufacturing apparatus, and then a series of the plurality of integrated surface emitting lasers 10-1 is separated from each other by dicing to obtain a plurality of chip-shaped surface emitting lasers 10.

In the first step S11, a multilayer body L is generated. Specifically, using a chemical vapor deposition (CVD) method, for example, a metal organic chemical vapor deposition (MOCVD) method, the first multilayer film reflector 102, the first cladding layer 103, the active layer 104, the second cladding layer 105, the second multilayer film reflector 106 including the selected oxide layers 10851 and 108S2 therein, and the contact layer 109 are layered in this order on the substrate 101 to generate the multilayer body L (see FIG. 4).

In the next step S12, a first resist pattern RP1 is formed. Specifically, as illustrated in FIG. 15, the resist pattern RP1 for forming the first mesa structure MS1 and the dummy region DA adjacent to the first mesa structure MS1 is formed on the multilayer body L. In the resist pattern RP1, an interval S1 between a portion for forming the first mesa structure MS1 and a portion for forming the dummy region DA adjacent to the first mesa structure MS1 is S.

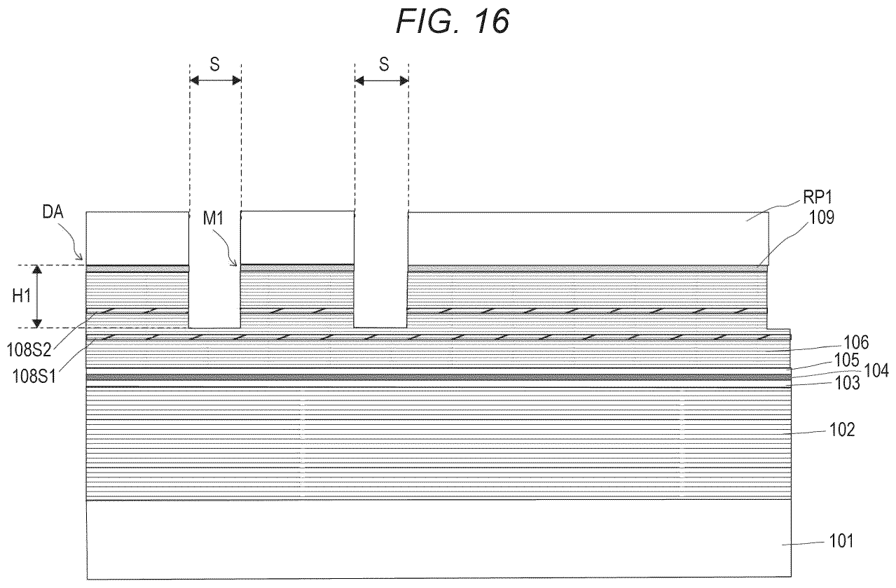

In the next step S13, the first mesa M1 is formed. Specifically, as illustrated in FIG. 16, the multilayer body is dry-etched or wet-etched using the resist pattern RP1 as a mask to form the first mesa M1 and the dummy region DA to be the first mesa structure MS1. Here, the etching is performed so that the bottom surface of the first mesa M1 (an etching bottom surface for forming the first mesa M1) is positioned between the selected oxide layer 10851 and the selected oxide layer 108S2 in the second multilayer film reflector 106 (so that the height dimension of the first mesa M1 becomes H1). As a result, the first mesa M1 having the height dimension H1 and the dummy region DA are formed.

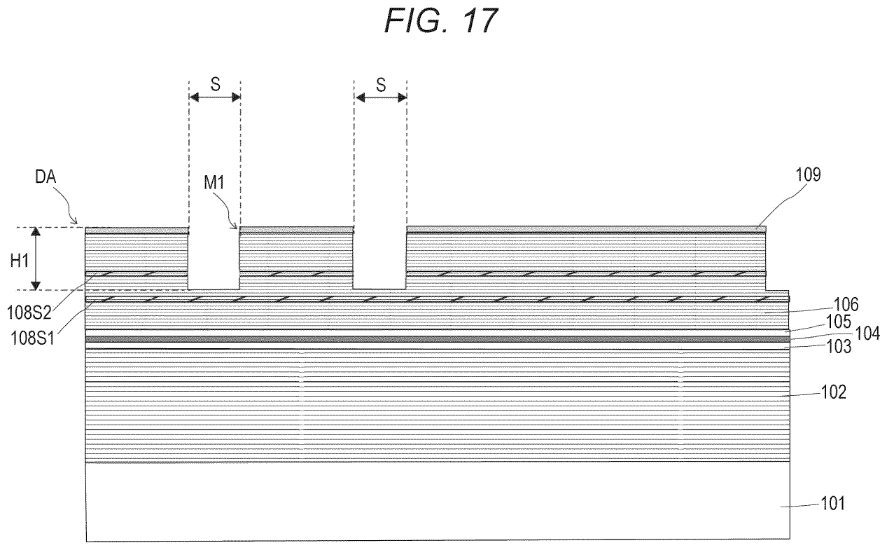

In the next step S14, the first resist pattern RP1 is removed (see FIG. 17).

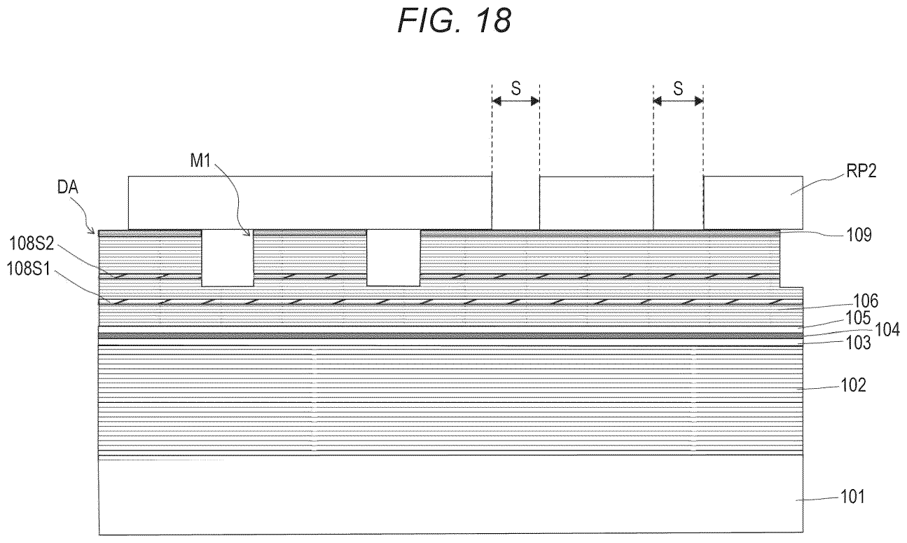

In the next step S15, a second resist pattern RP2 is formed. Specifically, as illustrated in FIG. 18, the resist pattern RP2 for forming the second mesa structure MS2 and the dummy region DA adjacent to the second mesa structure MS2 is formed on the multilayer body in which the first mesa M1 is formed. In the resist pattern RP2, an interval S2 between a portion for forming the second mesa structure MS2 and a portion for forming the dummy region DA adjacent to the second mesa structure MS2 is S.

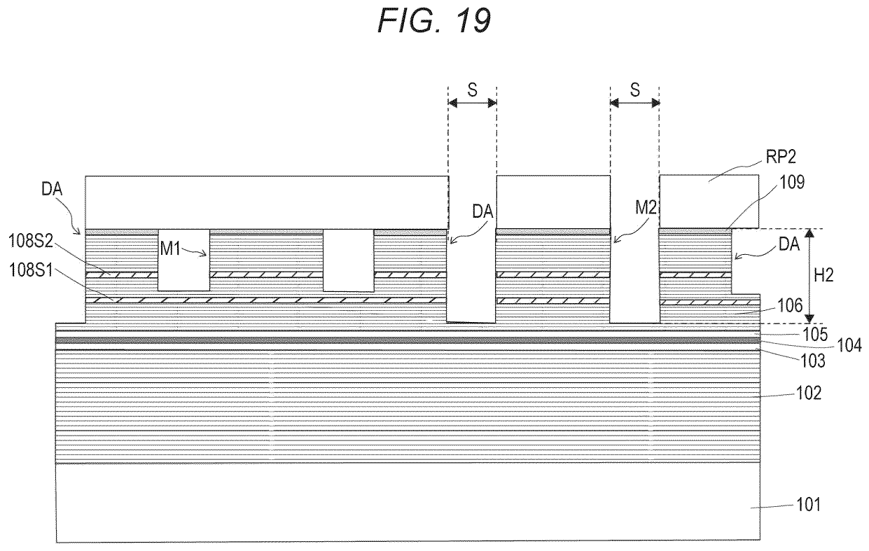

In the next step S16, the second mesa M2 is formed. Specifically, as illustrated in FIG. 19, the multilayer body in which the first mesa M1 is formed is dry-etched or wet-etched using the resist pattern RP2 as a mask to form the second mesa M2 to be the second mesa structure MS2 and the dummy region DA. Here, the etching is performed so that the bottom surface of the second mesa M2 (an etching bottom surface for forming the second mesa M2) is positioned between the second cladding layer 105 and the selected oxide layer 108S1 in the second multilayer film reflector 106 (so that the height dimension of the second mesa M2 becomes H2). As a result, the second mesa M2 having the height dimension H2 and the dummy region DA are formed.

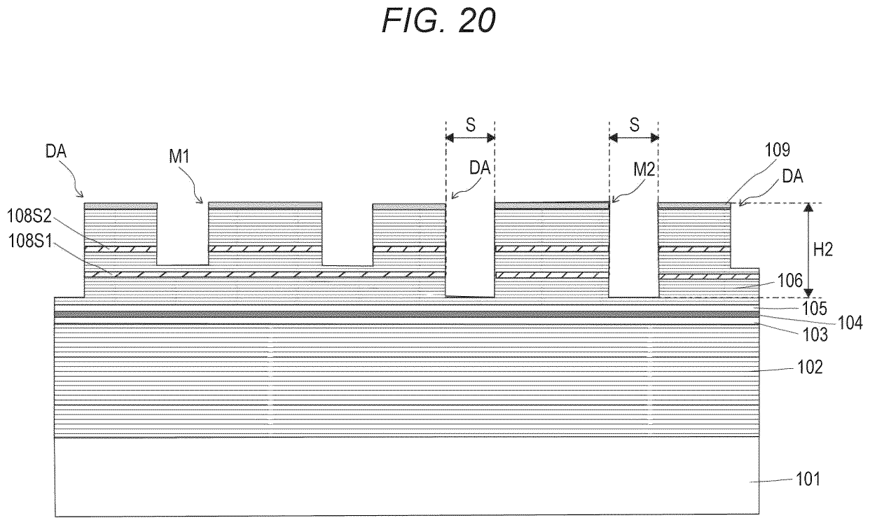

In the next step S17, the second resist pattern RP2 is removed (see FIG. 20).

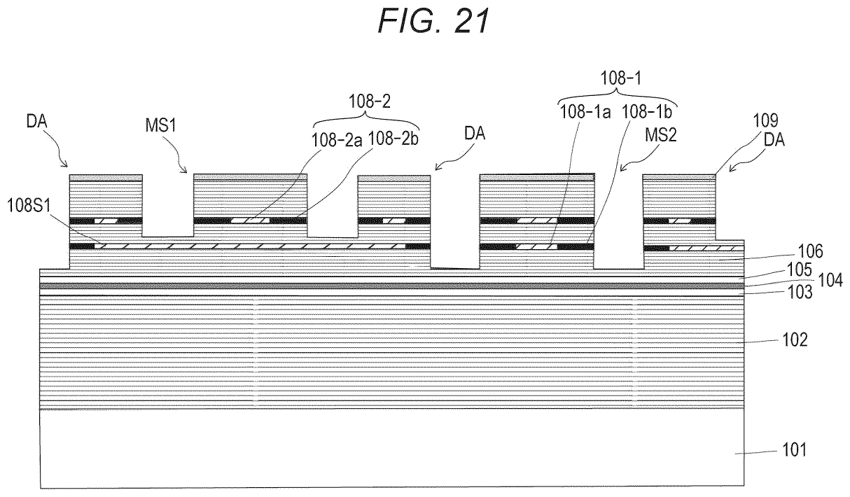

In the next step S18, oxide confinement layers are formed. Specifically, as illustrated in FIG. 21, peripheral portions of the selected oxide layer 108S2 (see FIG. 20) of the first mesa M1 and the selected oxide layers 108S1 and 108S2 (see FIG. 20) of the second mesa M2 are oxidized to form the first and second oxide confinement layers 108-1 and 108-2. More specifically, the first and second mesas M1 and M2 are exposed to a water vapor atmosphere, and the selected oxide layers 108S1 and 108S2 are oxidized (selectively oxidized) from the side surfaces to form the first and second oxide confinement layers 108-1 and 108-2 in which the periphery of the non-oxidized region is surrounded by the oxidized region. At this time, the peripheral portion of the selected oxide layer 10851 on the first mesa structure MS1 side is also oxidized. As a result, the first mesa M1 becomes the first mesa structure MS1, and the second mesa M2 becomes the second mesa structure MS2.

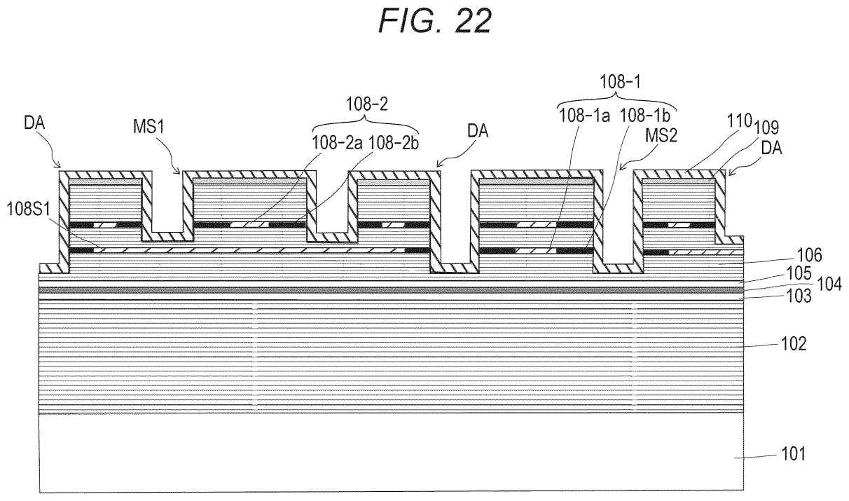

In the next step S19, the insulating film 110 is formed. Specifically, as illustrated in FIG. 22, the insulating film 110 is formed on the multilayer body in which the first and second mesa structures MS1 and MS2 and the dummy region DA are formed.

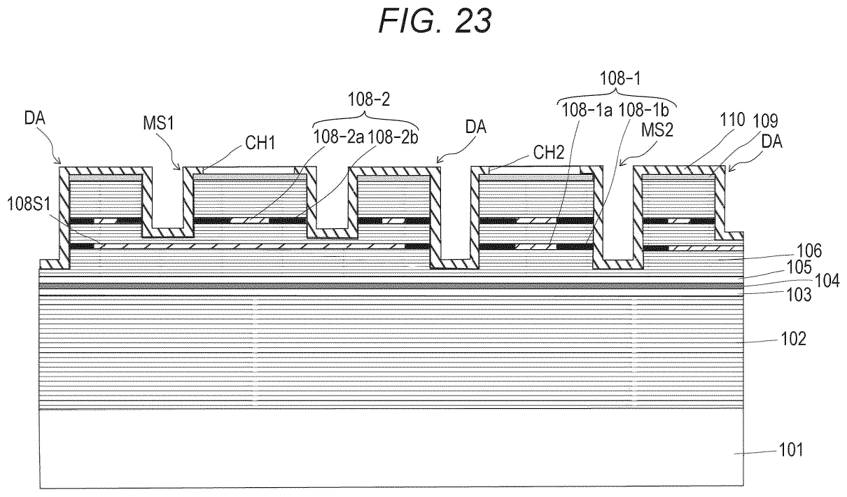

In the next step S20, the contact holes CH1 and CH2 are formed (see FIG. 23). Specifically, on the insulating film 110 of the multilayer body in which the first and second mesa structures MS1 and MS2 and the dummy region DA are formed and the insulating film 110 is formed, a resist pattern that covers a region other than the central portions of the tops of the first and second mesa structures MS1 and MS2 is generated. Next, dry etching or wet etching is performed using this resist pattern as a mask, and the insulating film 110 on the central portions of the tops of the first and second mesa structures MS1 and MS2 is removed to form the contact holes CH1 and CH2. Thus, the tops of the first and second mesa structures MS1 and MS2 are exposed.

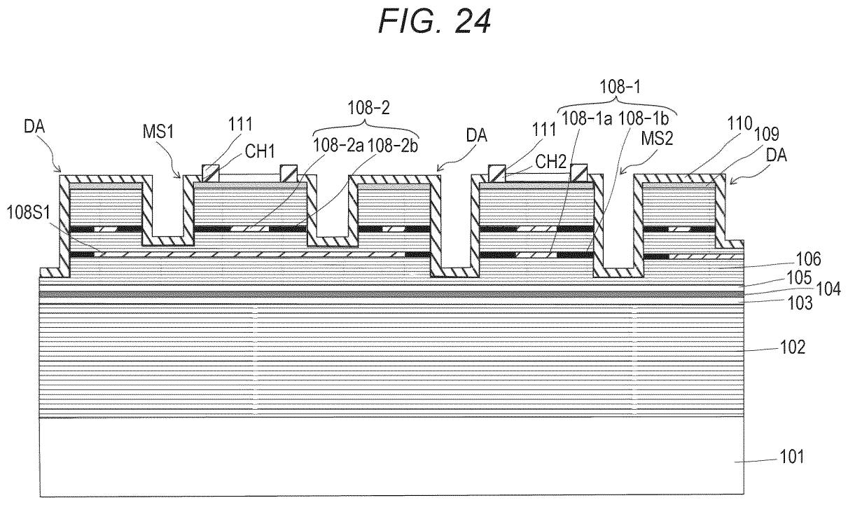

In the next step S21, the anode electrode 111 is formed (see FIG. 24). Specifically, for example, a resist is applied to a central region surrounded by a circling region where the anode electrode 111 is to be formed on the top of the first mesa structure MS1, an electrode material is formed on the top of the first mesa structure MS1 via the contact hole CH1 and an electrode material is formed on the top of the second mesa structure MS2 via the contact hole CH2 by an EB vapor deposition method, and the anode electrode 111 having a circling shape (for example, a ring shape) is formed on the top of the first and second mesa structures MS1 and MS2 by lifting off the resist and the electrode material on the resist.

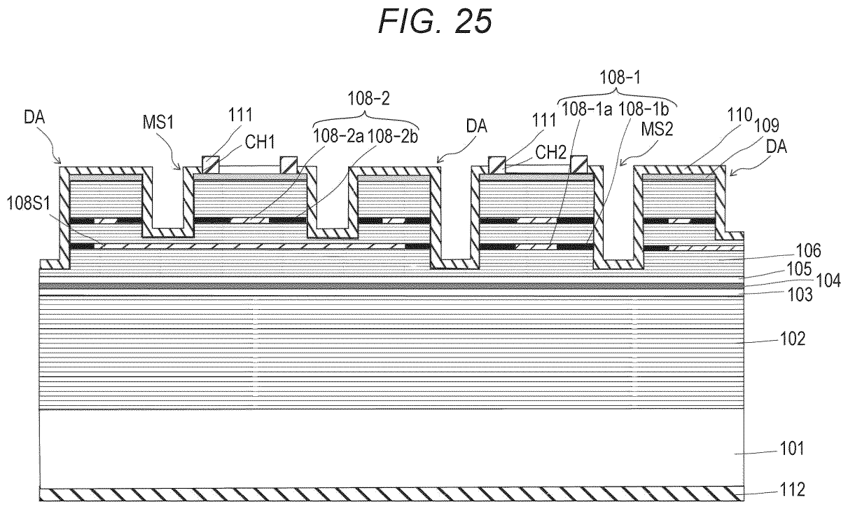

In the final step S22, the cathode electrode 112 is formed (see FIG. 25). Specifically, after the back surface of the substrate 101 is ground and thinned, an electrode material is formed on the back surface to form the cathode electrode 112.

Thereafter, post-processing such as annealing is performed, and a plurality of surface emitting lasers 10-1 is formed on one wafer.

Next, the electrode pads EP1 and EP2 are formed.

Next, each first electrode wiring EW1 is formed by, for example, a plating method so as to be in contact with the anode electrodes 111 of the corresponding plurality of first light emitting units 100-1 and to be in contact with the first electrode pad EP1. Moreover, each second electrode wiring EW2 is formed by, for example, a plating method so as to be in contact with the anode electrodes 111 of the corresponding plurality of second light emitting units 100-2 and to be in contact with the first electrode pad EP2. At this time, it is preferable to form a base layer (for example, nickel plating, chromium plating, or the like) to be a seed of plating by using, for example, vapor deposition, sputtering, or the like at portions of the insulating film 110 where the first and second electrode wirings EW1 and EW2 are to be formed. The first and second electrode wirings EW1 and EW2 are formed to have a thickness (for example, about 2 μm) that can sufficiently prevent a voltage drop. Thereafter, the plurality of surface emitting lasers 10-1 (here, the first and second electrode pads EP1 and EP2 are included) is separated from each other by dicing, and the plurality of chip-shaped surface emitting lasers 10-1 is obtained.

In the method for manufacturing the surface emitting laser 10-1 of the modification described above, since the first and second mesas M1 and M2 are separately formed, the first mesa structure MS1 having the height dimension H1 and the second mesa structure MS2 having the height dimension H2 (>H1) can be formed regardless of the magnitude relationship between the interval S1 between the first mesa structure MS1 and the dummy region DA adjacent to the first mesa structure MS1 and the interval S2 between the second mesa structure MS2 and the dummy region DA adjacent to the second mesa structure MS2. That is, although S1=S2=S here, the first and second mesa structures MS1 and MS2 can be formed with S1>S2 by a similar manufacturing method, or the first and second mesa structures MS1 and MS2 can be formed with S1<S2.

In the method for manufacturing the surface emitting laser 10-1, the second mesa M2 is formed after the first mesa M1 is formed, but the first mesa M1 may be formed after the second mesa M2 is formed.

<3. Surface Emitting Laser According to Second Embodiment of Present Technology>

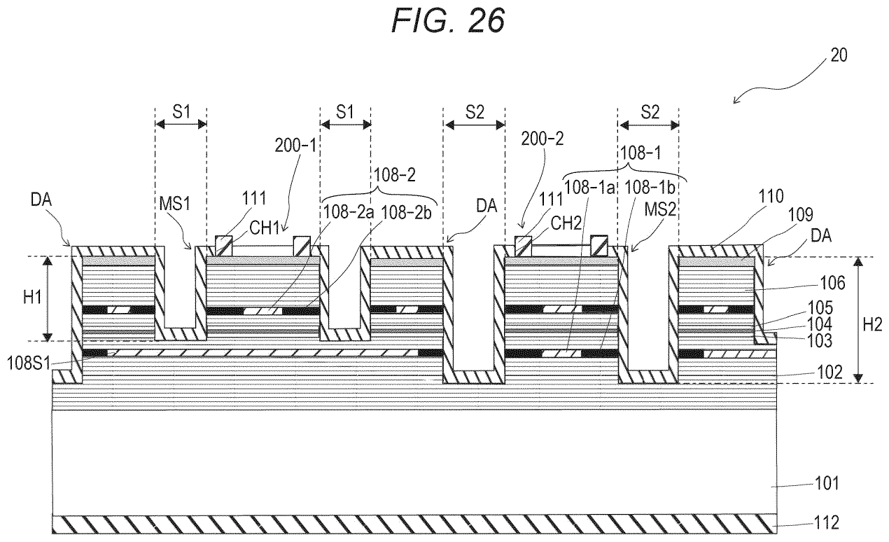

Hereinafter, a surface emitting laser 20 according to a second embodiment of the present technology will be described with reference to the drawings. FIG. 26 is a part of a cross-sectional view of the surface emitting laser 20 of the second embodiment (corresponding to a cross-sectional view taken along line A-A in FIG. 2).

As illustrated in FIG. 26, the surface emitting laser 20 of the second embodiment has a configuration substantially similar to that of the surface emitting laser 10 of the first embodiment except that both the first and second mesa structures MS1 and MS2 have the active layer 104 and that the first oxide confinement layer 108-1 is provided in the first multilayer film reflector 102 in the second mesa structure MS2.

As an example, a first light emitting unit 200-1 of the surface emitting laser 20 has the second oxide confinement layer 108-2 in the second multilayer film reflector 106 and the selected oxide layer 108S1 in the first multilayer film reflector 102.

As an example, the first mesa structure MS1 of the first light emitting unit 200-1 includes, in addition to the active layer 104, an upper portion of the first multilayer film reflector 102, the first cladding layer 103, the second cladding layer 105, the second multilayer film reflector 106, the second oxide confinement layer 108-2, and the contact layer 109.

As an example, the bottom surface of the first mesa structure MS1 of the first light emitting unit 200-1 is located between the selected oxide layer 108S1 and the first cladding layer 103 in the first multilayer film reflector 102.

As an example, the second light emitting unit 200-2 of the surface emitting laser 20 has the second oxide confinement layer 108-2 in the second multilayer film reflector 106, and has the first oxide confinement layer 108-1 in the first multilayer film reflector 102.

As an example, the second mesa structure MS2 of the second light emitting unit 200-2 includes, in addition to the active layer 104, an upper portion of the first multilayer film reflector 102, the first oxide confinement layer 108-1, the first cladding layer 103, the second cladding layer 105, the second multilayer film reflector 106, the second oxide confinement layer 108-2, and the contact layer 109.

As an example, the bottom surface of the second mesa structure MS2 of the second light emitting unit 200-2 is located between the first oxide confinement layer 108-1 and the substrate 101 in the first multilayer film reflector 102.

The surface emitting laser 20 can be manufactured by a manufacturing method according to the manufacturing method of the surface emitting laser 10 of the first embodiment.

Note that, in the surface emitting laser 20, S2>S1 and H2>H1 are satisfied, but as a modification, S2=S1 and H2>H1 may be satisfied, or S2<S1 and H2>H1 may be satisfied. However, in such a case, it is necessary to be manufactured by a manufacturing method according to the method for manufacturing the surface emitting laser 10-1 of the modification of the first embodiment.

Also in the surface emitting laser 20 described above, the second mesa structure MS2 has a larger height dimension than the first mesa structure MS1 (H2>H1), and the number of oxide confinement layers is larger. Thus, the surface emitting laser 20 has an effect similar to that of the surface emitting laser 10 of the first embodiment.

Moreover, in the surface emitting laser 20, the second mesa structure MS2 has one oxide confinement layer between the surface of the first multilayer film reflector 102 on the side opposite to the surface on the active layer 104 side and the active layer 104 and between the surface of the second multilayer film reflector 106 on the side opposite to the surface on the active layer 104 side and the active layer 104, and the first mesa structure MS1 has one oxide confinement layer between the surface of the second multilayer film reflector 106 on the side opposite to the surface on the active layer 104 side and the active layer 104.

That is, in the second light emitting unit 200-2 of the surface emitting laser 20, since the second mesa structure MS2 includes the active layer 104, it is possible to suppress a spread of carriers in the lateral direction in the active layer 104, and furthermore, the occurrence of the higher mode is further suppressed, and the single mode is more easily obtained.

<4. Surface Emitting Laser According to Third Embodiment of Present Technology>

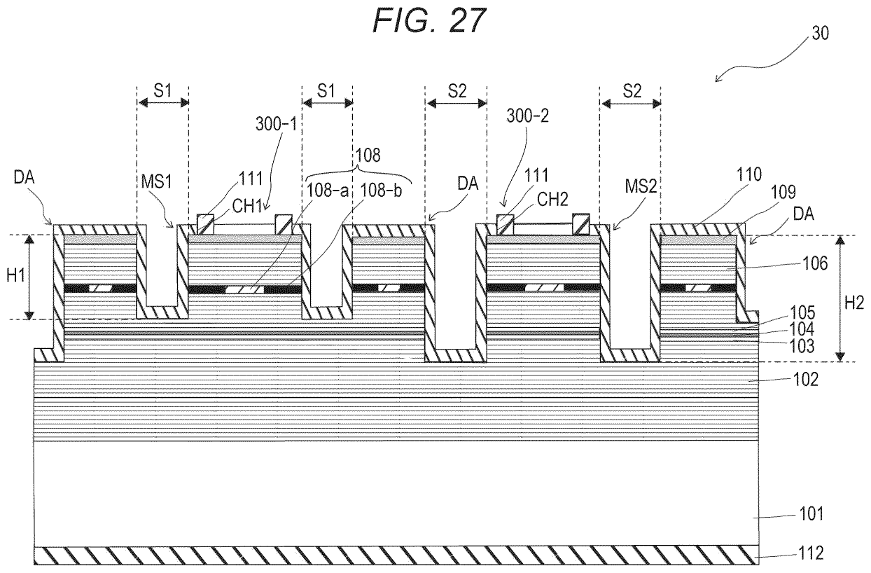

Hereinafter, a surface emitting laser 30 according to a third embodiment of the present technology will be described with reference to the drawings. FIG. 27 is a part of a cross-sectional view of the surface emitting laser 30 of the third embodiment (corresponding to a cross-sectional view taken along line A-A in FIG. 2).

As illustrated in FIG. 27, the surface emitting laser 30 of the third embodiment has a configuration substantially similar to that of the surface emitting laser 10 of the first embodiment except that the number of oxide confinement layers of the first and second mesa structures is the same and the number (including zero) of active layers 104 is larger in the second mesa structure MS2 than in the first mesa structure MS1 (more specifically, the first mesa structure MS1 does not have the active layer 104, and the second mesa structure MS2 has the active layer 104).

Also in the surface emitting laser 30, the second mesa structure MS2 has a larger height dimension than the first mesa structure MS1 (H2>H1).

In the surface emitting laser 30, as an example, both the first and second mesa structures MS1 and MS2 have one oxide confinement layer 108. The oxide confinement layer 108 has substantially the same configuration as the first and second oxide confinement layers 108-1 and 108-2.

The bottom surface of the first mesa structure MS1 of a first light emitting unit 300-1 of the surface emitting laser 30 is located between the second cladding layer 105 and the oxide confinement layer 108 in the second multilayer film reflector 106.

The bottom surface of the second mesa structure MS2 of a second light emitting unit 300-2 of the surface emitting laser 30 is located between the substrate 101 and the first cladding layer 103 in the first multilayer film reflector 102.

Each of the first and second mesa structures MS1 and MS2 has one oxide confinement layer between the surface of the second multilayer film reflector 106 on the side opposite to the surface on the active layer 104 side and the active layer 104.

According to the surface emitting laser 30, an effect similar to that of the surface emitting laser 10 of the first embodiment is obtained, and since the first and second mesa structures MS1 and MS2 have a single oxide confinement layer, the number of multilayer layers can be reduced.

In the second light emitting unit 300-2 of the surface emitting laser 30, since the second mesa structure MS2 includes the active layer 104, it is possible to suppress a spread of carriers in the lateral direction in the active layer 104, and eventually, the occurrence of the higher mode is further suppressed, and the single mode is more easily obtained.

Moreover, in the first light emitting unit 300-1 of the surface emitting laser 30, since the first mesa structure MS1 does not include the active layer 104, a spread of carriers in the lateral direction in the active layer 104 is not suppressed, the higher mode is likely to occur, and the multimode is likely to be obtained.

The surface emitting laser 30 can be manufactured by a manufacturing method according to the manufacturing method of the surface emitting laser 10 of the first embodiment.

The method for manufacturing the surface emitting laser 30 includes a step of layering the first multilayer film reflector 102, the active layer 104, at least one selected oxide layer (for example, one selected oxide layer), and the second multilayer film reflector 106 on the substrate 101 to generate a multilayer body, a step of etching the multilayer body to form a plurality of mesas including first and second mesas having different height dimensions and different numbers of active layers (including zero), and a step of selectively oxidizing the selected oxide layers of the plurality of mesas from side surfaces.

Note that, in the surface emitting laser 30, S2>S1 and H2>H1 are satisfied, but as a modification, S2=S1 and H2>H1 may be satisfied, or S2<S1 and H2>H1 may be satisfied. However, in such a case, it is necessary to be manufactured by a manufacturing method according to the method for manufacturing the surface emitting laser 10-1 of the modification of the first embodiment.

<5. Surface Emitting Laser According to Fourth Embodiment of Present Technology>

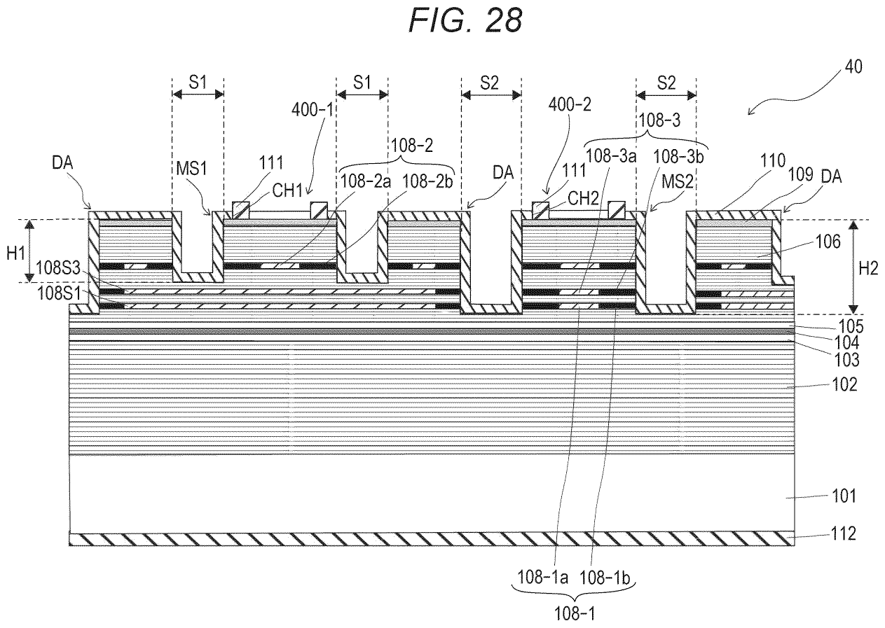

Hereinafter, a surface emitting laser 40 according to a fourth embodiment of the present technology will be described with reference to the drawings. FIG. 28 is a part of a cross-sectional view of the surface emitting laser 40 of the fourth embodiment (corresponding to a cross-sectional view taken along line A-A in FIG. 2).

As illustrated in FIG. 28, the surface emitting laser 40 of the fourth embodiment has a configuration substantially similar to that of the surface emitting laser 10 of the first embodiment except that the number of oxide confinement layers of the first mesa structure MS1 is one and the number of oxide confinement layers of the second mesa structure MS2 is three.

The second mesa structure MS2 of a second light emitting unit 400-2 of the surface emitting laser 40 has first to third oxide confinement layers 108-1 to 108-3 in the second multilayer film reflector 106. The third oxide confinement layer 108-3 is disposed between the first and second oxide confinement layers 108-1 and 108-2. The third oxide confinement layer 108-3 has a non-oxidized region 108-3a and an oxidized region 108-3b surrounding the non-oxidized region 108-3a. The third oxide confinement layer 108-3 has substantially the same configuration as the first and second oxide confinement layers 108-1 and 108-2.

The bottom surface of the second mesa structure MS2 of the second light emitting unit 400-2 is located between the second cladding layer 105 and the first oxide confinement layer 108-1 in the second multilayer film reflector 106.

The first light emitting unit 400-1 of the surface emitting laser 40 includes, in the second multilayer film reflector 106, the selected oxide layer 10851 to be a material of the first oxide confinement layer 108-1 and the selected oxide layer 10853 to be a material of the third oxide confinement layer 108-3.

The bottom surface of the first mesa structure MS1 of the first light emitting unit 400-1 is located between the selected oxide layer 10853 and the second oxide confinement layer 108-2 in the second multilayer film reflector 106.

The surface emitting laser 40 can be manufactured by a manufacturing method according to the manufacturing method of the surface emitting laser 10 of the first embodiment.

Note that, in the surface emitting laser 40, S2>S1 and H2>H1 are satisfied, but as a modification, S2=S1 and H2>H1 may be satisfied, or S2<S1 and H2>H1 may be satisfied. However, in such a case, it is necessary to be manufactured by a manufacturing method according to the method for manufacturing the surface emitting laser 10-1 of the modification of the first embodiment.

In the surface emitting laser 40, the second mesa structure MS2 of the second light emitting unit 400-2 has a larger height dimension than the first mesa structure MS1, and the number of oxide confinement layers is three, while the first mesa structure MS1 has one oxide confinement layer. Thus, the confinement effect of light and current of the second mesa structure MS2 can be made even larger than the confinement effect of light and current of the first mesa structure MS1.

That is, the second mesa structure MS2 of the second light emitting unit 400-2 is more suitable for generating spot light because the single mode is more easily obtained.

<6. Surface Emitting Laser According to Fifth Embodiment of Present Technology>

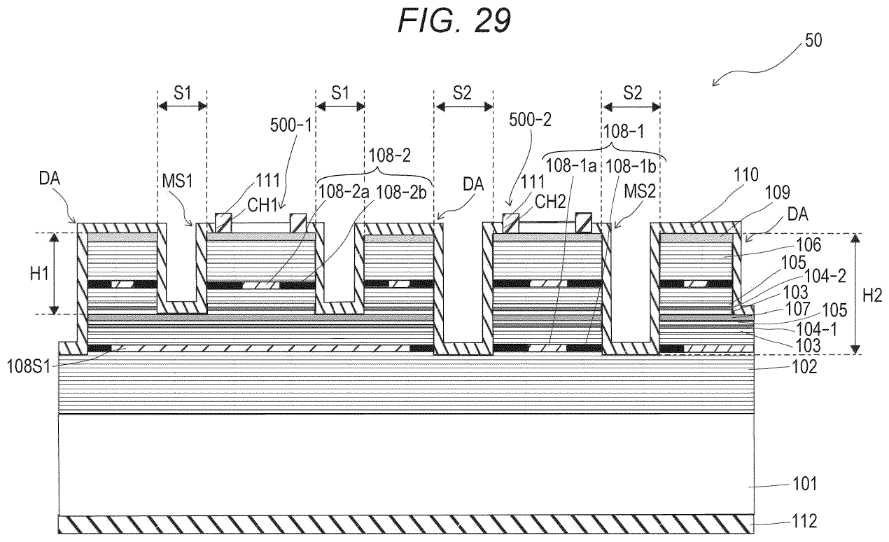

Hereinafter, a surface emitting laser 50 according to a fifth embodiment of the present technology will be described with reference to the drawings. FIG. 29 is a part of a cross-sectional view of the surface emitting laser 50 of the fifth embodiment (corresponding to a cross-sectional view taken along line A-A in FIG. 2).

As illustrated in FIG. 29, the surface emitting laser 50 of the fifth embodiment has a configuration substantially similar to that of the surface emitting laser 20 of the second embodiment except that the second mesa structure MS2 has first and second active layers 104-1 and 104-2 and a tunnel junction layer 107 between the first and second oxide confinement layers 108-1 and 108-2.

A first light emitting unit 500-1 of the surface emitting laser 50 includes the first multilayer film reflector 102, the selected oxide layer 108S1 disposed in the first multilayer film reflector 102, the first active layer 104-1, the first and second cladding layers 103 and 105 sandwiching the first active layer 104-1, the tunnel junction layer 107, the second active layer 104-2, the first and second cladding layers 103 and 105 sandwiching the second active layer 104-2, the second multilayer film reflector 106, the second oxide confinement layer 108-2 disposed in the second multilayer film reflector 106, and the contact layer 109. The second active layer 104-2 is located above the first active layer 104-1.

The tunnel junction layer 107 is disposed between the first and second active layers 104-1 and 104-2 (more specifically, between the second cladding layer 105 immediately above the first active layer 104-1 and the first cladding layer 103 immediately below the second active layer 104-2).

The tunnel junction layer 107 has a layer structure in which an n-type semiconductor region doped with impurities at a high concentration is layered on a p-type semiconductor region doped with impurities at a high concentration.

By disposing the tunnel junction layer 107 between the first and second active layers 104-1 and 104-2, a current of substantially the same magnitude can be injected into each of the first and second active layers 104-1 and 104-2.

As an example, the bottom surface of the first mesa structure MS1 of the first light emitting unit 500-1 is located between the first active layer 104-1 and the second active layer 104-2.

A second light emitting unit 500-2 of the surface emitting laser 50 includes the first multilayer film reflector 102, the first oxide confinement layer 108-1 disposed in the first multilayer film reflector 102, the first active layer 104-1, the first and second cladding layers 103 and 105 sandwiching the first active layer 104-1, the tunnel junction layer 107, the second active layer 104-2, the first and second cladding layers 103 and 105 sandwiching the second active layer 104-2, the second multilayer film reflector 106, the second oxide confinement layer 108-2 disposed in the second multilayer film reflector 106, and the contact layer 109. The second active layer 104-2 is located above the first active layer 104-1.

As an example, the bottom surface of the second mesa structure MS2 of the second light emitting unit 500-2 is located between the substrate 101 and the first oxide confinement layer 108-1 in the first multilayer film reflector 102.

The surface emitting laser 50 can be manufactured by a manufacturing method according to the manufacturing method of the surface emitting laser 10 of the first embodiment.

The method for manufacturing the surface emitting laser 50 includes a step of layering the first multilayer film reflector 102, the first and second active layers 104-1 and 104-2, the two selected oxide layers, and the second multilayer film reflector 106 on the substrate 101 to generate a multilayer body, a step of etching the multilayer body to form a plurality of mesas including first and second mesas having different height dimensions and different numbers (including zero) of active layers, and a step of selectively oxidizing the selected oxide layers of the plurality of mesas from side surfaces.

Note that, in the surface emitting laser 50, S2>S1 and H2>H1 are satisfied, but as a modification, S2=S1 and H2>H1 may be satisfied, or S2<S1 and H2>H1 may be satisfied. However, in such a case, it is necessary to be manufactured by a manufacturing method according to the method for manufacturing the surface emitting laser 10-1 of the modification of the first embodiment.

In the surface emitting laser 50, the first and second mesa structures MS1 and MS2 have different height dimensions, and the number of oxide confinement layers and the number of active layers are different.

In the surface emitting laser 50, the second mesa structure MS2 has a larger height dimension, a larger number of oxide confinement layers, and a larger number of active layers than the one-mesa structure MS1.

In the surface emitting laser 50, both the first and second mesa structures MS1 and MS2 have the active layer 104.

According to the surface emitting laser 50, an effect similar to that of the surface emitting laser 20 of the second embodiment is obtained, and the second mesa structure MS2 has the first and second active layers 104-1 and 104-2 and the first and second oxide confinement layers 108-1 and 108-2, so that it is possible to further suppress a spread of carriers in the lateral direction in each active layer and to further easily obtain the single mode.

<7. Surface Emitting Laser According to Sixth Embodiment of Present Technology>

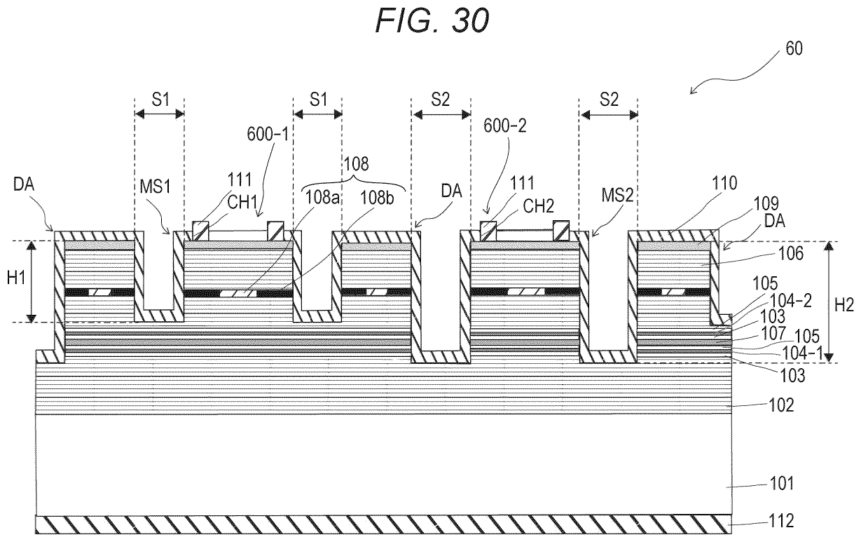

As illustrated in FIG. 30, a surface emitting laser 60 of the sixth embodiment has a configuration substantially similar to that of the surface emitting laser 30 of the third embodiment except that the second mesa structure MS2 has the first and second active layers 104-1 and 104-2 and the tunnel junction layer 107.

In the surface emitting laser 30, as an example, both the first and second mesa structures MS1 and MS2 have one oxide confinement layer 108. The oxide confinement layer 108 has substantially the same configuration as the first and second oxide confinement layers 108-1 and 108-2.

A first light emitting unit 600-1 of the surface emitting laser 60 includes the first multilayer film reflector 102, the first active layer 104-1, the first and second cladding layers 103 and 105 sandwiching the first active layer 104-1, the tunnel junction layer 107, the second active layer 104-2, the first and second cladding layers 103 and 105 sandwiching the second active layer 104-2, the second multilayer film reflector 106, the oxide confinement layer 108 disposed in the second multilayer film reflector 106, and the contact layer 109. The second active layer 104-2 is located above the first active layer 104-1.

The tunnel junction layer 107 is disposed between the first and second active layers 104-1 and 104-2 (more specifically, between the second cladding layer 105 immediately above the first active layer 104-1 and the first cladding layer 103 immediately below the second active layer 104-2).

The tunnel junction layer 107 has a layer structure in which an n-type semiconductor region doped with impurities at a high concentration is layered on a p-type semiconductor region doped with impurities at a high concentration.

By disposing the tunnel junction layer 107 between the first and second active layers 104-1 and 104-2, a current of substantially the same magnitude can be injected into each of the first and second active layers 104-1 and 104-2.

As an example, the bottom surface of the first mesa structure MS1 of the first light emitting unit 600-1 is located between the second cladding layer 105 immediately above the second active layer 104-2 in the second multilayer film reflector 106 and the oxide confinement layer 108.

The second light emitting unit 600-2 of the surface emitting laser 60 includes the first multilayer film reflector 102, the first active layer 104-1, the first and second cladding layers 103 and 105 sandwiching the first active layer 104-1, the tunnel junction layer 107, the second active layer 104-2, the first and second cladding layers 103 and 105 sandwiching the second active layer 104-2, the second multilayer film reflector 106, the oxide confinement layer 108 disposed in the second multilayer film reflector 106, and the contact layer 109. The second active layer 104-2 is located above the first active layer 104-1.

As an example, the bottom surface of the second mesa structure MS2 of the second light emitting unit 600-2 is located between the substrate 101 and the first cladding layer 103 immediately below the first active layer 104-1 in the first multilayer film reflector 102.

The surface emitting laser 60 can be manufactured by a manufacturing method according to the manufacturing method of the surface emitting laser 10 of the first embodiment.

Note that, in the surface emitting laser 60, S2>S1 and H2>H1 are satisfied, but as a modification, S2=S1 and H2>H1 may be satisfied, or S2<S1 and H2>H1 may be satisfied. However, in such a case, it is necessary to be manufactured by a manufacturing method according to the method for manufacturing the surface emitting laser 10-1 of the modification of the first embodiment.

According to the surface emitting laser 60, an effect similar to that of the surface emitting laser 30 of the third embodiment is obtained, and the second mesa structure MS2 has the first and second active layers 104-1 and 104-2 and the oxide confinement layer 108, so that it is possible to further suppress a spread of carriers in the lateral direction in each active layer and to more easily obtain the single mode.

<8. Modification of Present Technology>

The surface emitting laser of each embodiment and each modification described above can be appropriately changed.

It is preferable that the first and second light emitting units of the surface emitting laser of each of the embodiments and modifications described above include at least one oxide confinement layer disposed between the surface of the first multilayer film reflector 102 on the side opposite to the surface on the active layer side and the active layer and/or between the surface of the second multilayer film reflector on the side opposite to the surface on the active layer side and the active layer.

The number of oxide confinement layers of the first and second mesa structures MS1 and MS2 can be appropriately changed.

For example, the number of oxide confinement layers of the first mesa structure MS1 may be zero or plural.

For example, the number of oxide confinement layers of the second mesa structure MS2 may be equal to or more than four.

In any case, the second mesa structure MS2 preferably has a larger number of oxide confinement layers than the first mesa structure MS1.

The number of active layers of the first and second mesa structures MS1 and MS2 can be appropriately changed.

For example, the number of active layers of the first mesa structure MS1 may be equal to or more than two.

For example, the number of active layers of the second mesa structure MS2 may be equal to or more than three.

In any case, the second mesa structure MS2 preferably has a larger number of active layers than the first mesa structure MS1.

The mesa structure including a plurality of active layers preferably has a tunnel junction layer between two adjacent active layers.

For example, it is also possible to provide a surface emitting laser whose conductivity type (p-type and n-type) is opposite to that of the surface emitting laser of each of the embodiments and modifications described above.

For example, the surface emitting laser of each of the embodiments and modifications described above can also be applied to a back surface emitting vertical cavity surface emitting laser (VCSEL) that emits light from the back surface side of the substrate 101.

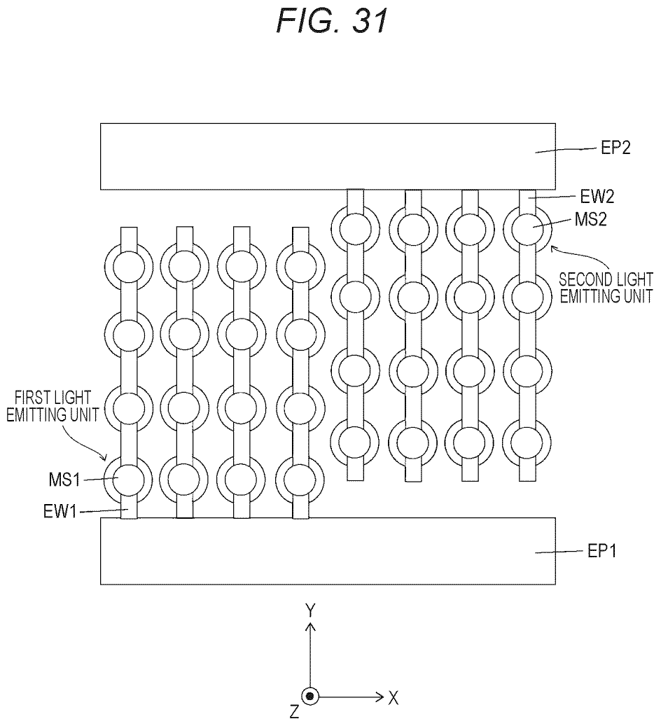

For example, in the surface emitting laser of each of the embodiments and modifications described above, as illustrated in FIG. 31, the first light emitting unit row group in which the plurality of first light emitting unit rows in which the plurality of first light emitting units having the first mesa structure MS1 is arranged in the Y-axis direction is arranged side by side in the X-axis direction and the second light emitting unit row group in which the plurality of second light emitting unit rows in which the plurality of second light emitting units having the second mesa structure MS2 is arranged in the Y-axis direction is arranged side by side in the X-axis direction may be arranged in different regions in the X-axis direction.

For example, the surface emitting laser of each of the embodiments and modifications described above has two types of mesa structures of the first and second mesa structures MS1 and MS2, but may further have at least one type of mesa structure having a different height dimension from the first and second mesa structures MS1 and MS2 and having a different number of oxide confinement layers and/or active layers. Examples of such a mesa structure include a mesa structure having an intermediate optical and electrical confinement effect between the first and second mesa structures.

For example, in a case of having three or more types of mesa structures, three types of light emitting unit rows may be alternately arranged following the example of FIG. 2, or three types of light emitting unit row groups may be separately arranged in three or more regions following the example of FIG. 31.

For example, the surface emitting laser of each of the embodiments and modifications described above may not include the contact layer 109.

For example, the surface emitting laser of each of the embodiments and modifications described above may have a buffer layer between the substrate 101 and the first multilayer film reflector 102.

For example, in the surface emitting laser of each of the embodiments and modifications described above, at least one of the first and second multilayer film reflectors 102 and 106 may be a dielectric multilayer film reflector.

Some of the configurations of the surface emitting lasers of the embodiments and modifications described above may be combined within a range in which they do not contradict each other.

In each of the embodiments and modifications described above, the material, conductivity type, thickness, width, length, shape, size, arrangement, and the like of each component constituting the surface emitting laser can be appropriately changed within a range functioning as the surface emitting laser.

9. Application Example to Electronic Device

The technology according to the present disclosure (the present technology) can be applied to various products (electronic devices). For example, the technology according to the present disclosure may be implemented as a device mounted on any type of mobile body such as an automobile, an electric vehicle, a hybrid electric vehicle, a motorcycle, a bicycle, a personal mobility, an airplane, a drone, a ship, and a robot.

10. <Example of Applying Surface Emitting Laser to Distance Measuring Device>

Hereinafter, application examples of the surface emitting laser according to each of the embodiments and modifications described above will be described.

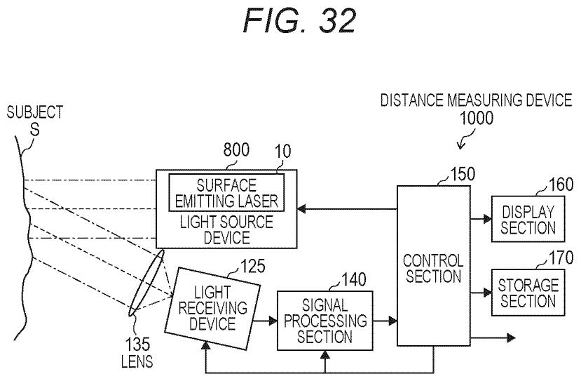

FIG. 32 illustrates an example of a schematic configuration of a distance measuring device 1000 including the surface emitting laser 10 as an example of an electronic device according to the present technology. The distance measuring device 1000 measures the distance to a subject S by a time of flight (TOF) method. The distance measuring device 1000 includes the surface emitting laser 10 as a light source. The distance measuring device 1000 includes, for example, a light source device 800 including the surface emitting laser 10, a light receiving device 125, a lens 135, a signal processing section 140, a control section 150, a display section 160, and a storage section 170.

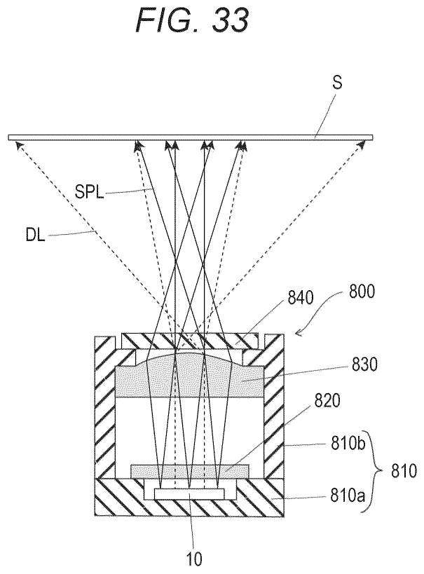

As an example, as illustrated in FIG. 33, in addition to the surface emitting laser 10, the light source device 800 includes a housing 810, a microlens array 820, a collimator lens 830, a diffractive optical element 840 as a diffusion plate, and a laser driver having a driver IC. The microlens array 820 includes a lens portion having a condensing function and a flat portion having no condensing function.

The light emitted from the first light emitting unit 100-1 of the surface emitting laser 10 passes through the flat portion of the microlens array 820 as it is and enters the collimator lens 830, is converted into substantially parallel light by the collimator lens 830, is diffracted while being divided by the diffractive optical element 840 (while the number of spots is increased), and is applied to the subject S as spot light SPL. As described above, the light emitted from the first light emitting unit 100-1 has high directivity, so that the measured distance can be increased, but has low resolution because the light is emitted in a dot-like manner. In this case, it is desirable that the spot size (the diameter of the spot light SPL) hardly changes depending on the incident position on the collimator lens 830. In the light emitted from the first light emitting unit 100-1, since the single mode is dominant in the horizontal mode, the spot size is less likely to change, and the light is particularly suitable for the purpose of extending the measured distance.

The light emitted from the second light emitting unit 100-2 of the surface emitting laser 10 passes through the lens portion of the microlens array 820, is condensed between the collimator lens 830 and the diffractive optical element 840, is diffracted while being divided (overlapping) by the diffractive optical element 840, and is applied to the subject S as the diffused light DL. As described above, since the light emitted from the second light emitting unit 100-2 has low directivity, the measured distance cannot be increased, but since uniform irradiation is performed, the resolution is high, and the distance measurement accuracy can be improved. In this case, it is desirable to easily defocus the collimator lens 830. The light emitted from the second light emitting unit 100-2 is easily defocused since the multimode is dominant in the lateral mode, and is particularly suitable for the use of improving the distance measurement accuracy.

Returning to FIG. 32, the light receiving device 125 detects the light reflected by the subject S. The lens 135 is a lens for condensing light reflected by the subject S and guiding the light to the light receiving device 125, and is a condenser lens.

The signal processing section 140 is a circuit for generating a signal corresponding to a difference between a signal input from the light receiving device 125 and a reference signal input from the control section 150.

The control section 150 includes, for example, a time-to-digital converter (TDC). The reference signal may be a signal input from the control section 150, or may be an output signal of a detection section that directly detects the output of the surface emitting laser 10. The control section 150 is, for example, a processor that controls the surface emitting laser 10, the light receiving device 125, the signal processing section 140, the display section 160, and the storage section 170.

The control section 150 applies a first light emission signal for driving a first light emitting unit group including a plurality of the first light emitting units 100-1 and a second light emission signal for driving a second light emitting unit group including a plurality of the second light emitting units 100-2 to the laser driver at different timings, thereby causing the first light emitting unit group and the second light emitting unit group to emit light at different timings. Thus, spot light irradiation for increasing the measured distance to the subject S and diffused light irradiation for improving the distance measurement accuracy can be switched and performed.

The control section 150 measures a distance to the subject S on the basis of a signal generated by the signal processing section 140. The control section 150 generates a video signal for displaying information about the distance to the subject S, and outputs the video signal to the display section 160. The display section 160 displays information about the distance to the subject S on the basis of the video signal input from the control section 150. The control section 150 stores information about the distance to the subject S in the storage section 170.

In the present application example, instead of the surface emitting laser 10, any one of the surface emitting lasers 10-1, 20, 30, 40, 50, and 60 described above can be applied to the distance measuring device 1000.

11. <Example in which Distance Measuring Device is Mounted on Mobile Body>

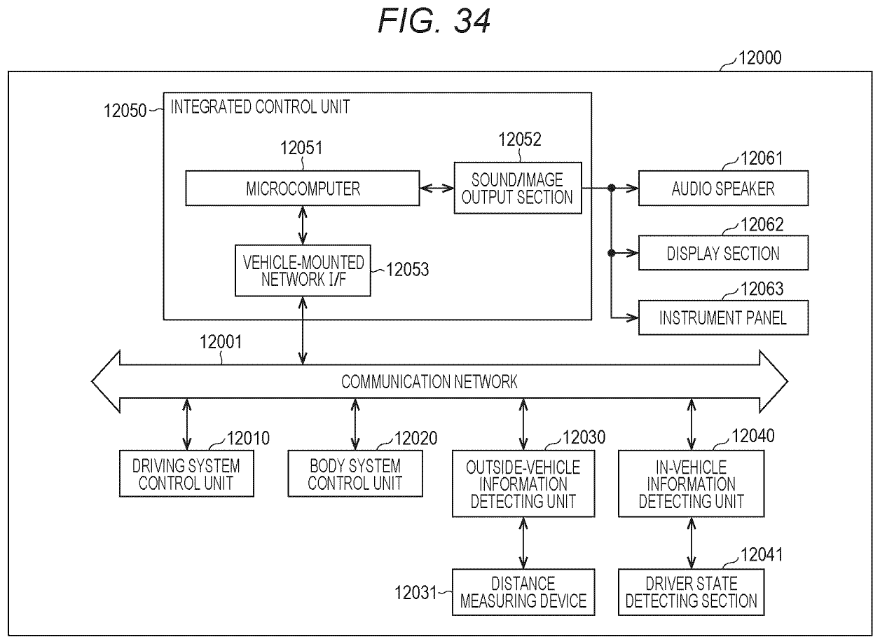

FIG. 34 is a block diagram illustrating a schematic configuration example of a vehicle control system that is an example of a mobile body control system to which the technology according to the present disclosure can be applied.

The vehicle control system 12000 includes a plurality of electronic control units connected to each other via a communication network 12001. In the example depicted in FIG. 34, the vehicle control system 12000 includes a driving system control unit 12010, a body system control unit 12020, an outside-vehicle information detecting unit 12030, an in-vehicle information detecting unit 12040, and an integrated control unit 12050.

Furthermore, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device of a driving force generation device for generating a driving force of the vehicle, such as an internal combustion engine or a driving motor, a driving force transmission mechanism for transmitting the driving force to wheels, a steering mechanism for adjusting a steering angle of the vehicle, a braking device for generating a braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various lamps such as a headlamp, a back lamp, a brake lamp, a turn indicator, or a fog lamp. In this case, a radio wave transmitted from a portable device that substitutes for a key or signals of various switches may be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, a distance measuring device 12031 is connected to the outside-vehicle information detecting unit 12030. The distance measuring device 12031 includes the above-described distance measuring device 1000. The outside-vehicle information detecting unit 12030 causes the distance measuring device 12031 to measure a distance to an object (subject S) outside the vehicle, and acquires distance data obtained by the measurement. The outside-vehicle information detecting unit 12030 may perform object detection processing of a person, a vehicle, an obstacle, a sign, or the like on the basis of the acquired distance data.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041 includes, for example, a camera that captures an image of the driver, and the in-vehicle information detecting unit 12040 may calculate the degree of fatigue or the degree of concentration of the driver or may determine whether or not the driver is dozing off on the basis of the detection information input from the driver state detecting section 12041.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020 on the basis of the information about the outside of the vehicle acquired by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound or an image to an output device capable of visually or auditorily notifying an occupant of the vehicle or the outside of the vehicle of information. In the example of FIG. 34, an audio speaker 12061, a display section 12062, and an instrument panel 12063 are illustrated as the output device. The display section 12062 may, for example, include at least one of an on-board display or a head-up display.

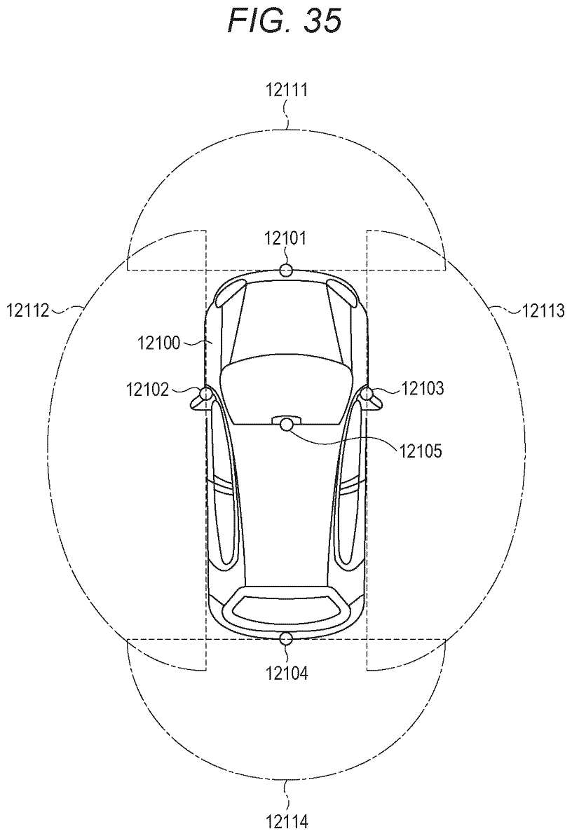

FIG. 35 is a view illustrating an example of an installation position of distance measuring device 12031.

In FIG. 35, a vehicle 12100 includes distance measuring devices 12101, 12102, 12103, 12104, and 12105 as the distance measuring device 12031.

The distance measuring devices 12101, 12102, 12103, 12104, and 12105 are provided at positions such as, for example, a front nose, side mirrors, a rear bumper, a back door, and an upper part of a windshield in a vehicle cabin, of the vehicle 12100. The distance measuring device 12101 provided on the front nose and the distance measuring device 12105 provided on the upper part of the windshield in the cabin mainly acquire data of the front side of the vehicle 12100. The distance measuring devices 12102 and 12103 provided at the side mirrors mainly acquire data on the sides of the vehicle 12100. The distance measuring device 12104 provided on the rear bumper or the back door mainly acquires data behind the vehicle 12100. The data of the front side acquired by the distance measuring devices 12101 and 12105 is mainly used for detecting a preceding vehicle, a pedestrian, an obstacle, a traffic light, a traffic sign, or the like.

Note that FIG. 35 illustrates an example of detection ranges of the distance measuring devices 12101 to 12104. A detection range 12111 indicates a detection range of the distance measuring device 12101 provided on the front nose, detection ranges 12112 and 12113 indicate detection ranges of the distance measuring devices 12102 and 12103 provided at the side mirrors, respectively, and a detection range 12114 indicates a detection range of the distance measuring device 12104 provided on the rear bumper or the back door.

For example, the microcomputer 12051 can determine a distance to each three-dimensional object within the detection ranges 12111 to 12114 and a temporal change in the distance (a relative speed with respect to the vehicle 12100) on the basis of the distance data obtained from the distance measuring devices 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Moreover, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance data obtained from the distance measuring devices 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle, and when the collision risk is equal to or higher than a set value and there is a possibility of collision, the microcomputer 12051 can perform driving assistance for collision avoidance by outputting an alarm to the driver via the audio speaker 12061 or the display section 12062 or performing forced deceleration or avoidance steering via the driving system control unit 12010.

An example of the mobile body control system to which the technology according to the present disclosure can be applied has been described above. The technology according to the present disclosure can be applied to the distance measuring device 12031 among the configurations described above.

Furthermore, the present technology can also have the following configurations.

(1) A surface emitting laser, including:
a plurality of light emitting units having a mesa structure, the light emitting units each including
a first multilayer film reflector,
a second multilayer film reflector,
an active layer disposed between the first and second multilayer film reflectors,
at least one oxide confinement layer disposed between a surface of the first multilayer film reflector on a side opposite to a surface on a side of the active layer and the active layer and/or between a surface of the second multilayer film reflector on a side opposite to a surface on a side of the active layer and the active layer, in which
the mesa structures of the plurality of light emitting units include first and second mesa structures having different height dimensions, and having different numbers of the oxide confinement layers and/or different numbers of the active layers.

(2) The surface emitting laser according to (1), in which the second mesa structure has a larger height dimension and a larger number of the oxide confinement layers than the first mesa structure.

(3) The surface emitting laser according to (1) or (2), in which the light emitting unit having the first mesa structure includes at least one layer to be a material of the oxide confinement layer.

(4) The surface emitting laser according to any one of (1) to (3), in which the second mesa structure has the active layer, and the first mesa structure does not have the active layer.

(5) The surface emitting laser according to any one of (1) to (3), in which both the first and second mesa structures have the active layer.

(6) The surface emitting laser according to any one of (1) to (3), in which both the first and second mesa structures do not have the active layer.

(7) The surface emitting laser according to any one of (1) to (6), in which the second mesa structure includes a plurality of the oxide confinement layers on one side between the surface of the first multilayer film reflector on the side opposite to the surface on the side of the active layer and the active layer or between the surface of the second multilayer film reflector on the side opposite to the surface on the side of the active layer and the active layer, and the first mesa structure includes at least one oxide confinement layer on the one side.

(8) The surface emitting laser according to any one of (1) to (6), in which the second mesa structure includes at least one of the oxide confinement layers between the surface of the first multilayer film reflector on the side opposite to the surface on the side of the active layer and the active layer and between the surface of the second multilayer film reflector on the side opposite to the surface on the side of the active layer and the active layer, and the first mesa structure includes at least one of the oxide confinement layers on one side between the surface of the first multilayer film reflector on the side opposite to the surface on the side of the active layer and the active layer or between the surface of the second multilayer film reflector on the side opposite to the surface on the side of the active layer and the active layer.

(9) The surface emitting laser according to (1), in which the first and second mesa structures have a same number of oxide confinement layers, and the second mesa structure has a larger height dimension and a larger number of the active layers than the first mesa structure.

(10) The surface emitting laser according to (9), in which each of the first and second mesa structures includes at least one of the oxide confinement layers on one side between the surface of the first multilayer film reflector on the side opposite to the surface on the side of the active layer and the active layer or between the surface of the second multilayer film reflector on the side opposite to the surface on the side of the active layer and the active layer.

(11) The surface emitting laser according to any one of (1) to (10), further including a dummy region between the first and second mesa structures.

(12) The surface emitting laser according to (11), in which an interval between the first mesa structure and the dummy region is different from an interval between the second mesa structure and the dummy region.

(13) The surface emitting laser according to (11) or (12), in which the second mesa structure has a larger height dimension than the first mesa structure, and the interval between the second mesa structure and the dummy region is larger than the interval between the first mesa structure and the dummy region.

(14) The surface emitting laser according to (11) or (12), in which
the second mesa structure has a larger height dimension than the first mesa structure, and
an interval between the second mesa structure and the dummy region is equal to or less than an interval between the first mesa structure and the dummy region.

(15) A light source device, including:
the surface emitting laser according to any one of (1) to (14);
a diffusion plate disposed on a top side of a first mesa structure of the surface emitting laser; and
a collimator lens disposed on a top side of a second mesa structure of the surface emitting laser.

(16) An electronic device including the surface emitting laser according to any one of (1) to (14).

(17) The electronic device according to (16), in which the electronic device is a distance measuring device.

(18) A method for manufacturing a surface emitting laser, the method including:
layering a first multilayer film reflector, at least one active layer, a plurality of selected oxide layers, and a second multilayer film reflector on a substrate to form a multilayer body;
etching the multilayer body to form a plurality of mesas including first and second mesas having different height dimensions and different numbers of the selected oxide layers; and
selectively oxidizing the selected oxide layer of the plurality of mesas from a side surface.

(19) A method for manufacturing a surface emitting laser, the method including:
layering a first multilayer film reflector, at least one active layer, at least one selected oxide layer, and a second multilayer film reflector on a substrate to form a multilayer body;
etching the multilayer body to form a plurality of mesas including first and second mesas having different height dimensions and different numbers of the active layers; and
selectively oxidizing the selected oxide layer of the plurality of mesas from a side surface.

### REFERENCE SIGNS LIST

10, 10-1, 20, 30, 40, 50, 60 Surface emitting laser
100-1, 200-1, 300-1, 400-1, 500-1, 600-1 First light emitting unit (light emitting unit having first mesa structure)
100-2, 200-2, 300-2, 400-2, 500-2, 600-2 (Light emitting unit having second mesa structure)
101 Substrate
102 First multilayer film reflector
104 Active layer
104-1 First active layer (active layer)
104-2 Second active layer (active layer)
106 Second multilayer film reflector
108 Oxide confinement layer
108-1 First oxide confinement layer (oxide confinement layer)
108-2 Second oxide confinement layer (oxide confinement layer)
108-2 Third oxide confinement layer (oxide confinement layer)
108S1, 108S2, 108 S3 Selected oxide layer
800 Light source device
830 Collimator lens
840 Diffractive optical element (diffusion plate)
MS1 First mesa structure
MS2 Second mesa structure
DA Dummy region
M1 First mesa
M2 Second mesa
L Multilayer body

1. A surface emitting laser, comprising:
a plurality of light emitting units having a mesa structure, the light emitting units each including
a first multilayer film reflector,
a second multilayer film reflector,
an active layer disposed between the first and second multilayer film reflectors,
at least one oxide confinement layer disposed between a surface of the first multilayer film reflector on a side opposite to a surface on a side of the active layer and the active layer and/or between a surface of the second multilayer film reflector on a side opposite to a surface on a side of the active layer and the active layer, wherein
the mesa structures of the plurality of light emitting units include first and second mesa structures having different height dimensions, and having different numbers of the oxide confinement layers and/or different numbers of the active layers.

2. The surface emitting laser according to claim 1, wherein the second mesa structure has a larger height dimension and a larger number of the oxide confinement layers than the first mesa structure.

3. The surface emitting laser according to claim 2, wherein the light emitting unit having the first mesa structure includes at least one layer to be a material of the oxide confinement layer.

4. The surface emitting laser according to claim 2, wherein the second mesa structure has the active layer, and the first mesa structure does not have the active layer.

5. The surface emitting laser according to claim 2, wherein both the first and second mesa structures have the active layer.

6. The surface emitting laser according to claim 2, wherein both the first and second mesa structures do not have the active layer.

7. The surface emitting laser according to claim 2, wherein
the second mesa structure includes a plurality of the oxide confinement layers on one side between the surface of the first multilayer film reflector on the side opposite to the surface on the side of the active layer and the active layer or between the surface of the second multilayer film reflector on the side opposite to the surface on the side of the active layer and the active layer, and
the first mesa structure includes at least one oxide confinement layer on the one side.

8. The surface emitting laser according to claim 2, wherein
the second mesa structure includes at least one of the oxide confinement layers between the surface of the first multilayer film reflector on the side opposite to the surface on the side of the active layer and the active layer and between the surface of the second multilayer film reflector on the side opposite to the surface on the side of the active layer and the active layer, and
the first mesa structure includes at least one of the oxide confinement layers on one side between the surface of the first multilayer film reflector on the side opposite to the surface on the side of the active layer and the active layer or between the surface of the second multilayer film reflector on the side opposite to the surface on the side of the active layer and the active layer.

9. The surface emitting laser according to claim 1, wherein
the first and second mesa structures have a same number of oxide confinement layers, and
the second mesa structure has a larger height dimension and a larger number of the active layers than the first mesa structure.

10. The surface emitting laser according to claim 9, wherein each of the first and second mesa structures includes at least one of the oxide confinement layers on one side between the surface of the first multilayer film reflector on the side opposite to the surface on the side of the active layer and the active layer or between the surface of the second multilayer film reflector on the side opposite to the surface on the side of the active layer and the active layer.

11. The surface emitting laser according to claim 1, further comprising a dummy region between the first and second mesa structures.

12. The surface emitting laser according to claim 11, wherein an interval between the first mesa structure and the dummy region is different from an interval between the second mesa structure and the dummy region.

13. The surface emitting laser according to claim 12, wherein
the second mesa structure has a larger height dimension than the first mesa structure, and
the interval between the second mesa structure and the dummy region is larger than the interval between the first mesa structure and the dummy region.

14. The surface emitting laser according to claim 11, wherein
the second mesa structure has a larger height dimension than the first mesa structure, and
an interval between the second mesa structure and the dummy region is equal to or less than an interval between the first mesa structure and the dummy region.

15. A light source device, comprising:
the surface emitting laser according to claim 2; and
a diffusion plate disposed on a top side of a first mesa structure of the surface emitting laser; and
a collimator lens disposed on a top side of a second mesa structure of the surface emitting laser.

16. A light source device, comprising:
the surface emitting laser according to claim 9;
a diffusion plate disposed on a top side of a first mesa structure of the surface emitting laser; and
a collimator lens disposed on a top side of a second mesa structure of the surface emitting laser.

17. An electronic device comprising the surface emitting laser according to claim 1.

18. The electronic device according to claim 17, wherein the electronic device is a distance measuring device.

19. A method for manufacturing a surface emitting laser, the method comprising:
layering a first multilayer film reflector, at least one active layer, a plurality of selected oxide layers, and a second multilayer film reflector on a substrate to form a multilayer body;
etching the multilayer body to form a plurality of mesas including first and second mesas having different height dimensions and different numbers of the selected oxide layers; and
selectively oxidizing the selected oxide layer of the plurality of mesas from a side surface.

20. A method for manufacturing a surface emitting laser, the method comprising:
layering a first multilayer film reflector, at least one active layer, at least one selected oxide layer, and a second multilayer film reflector on a substrate to form a multilayer body;
etching the multilayer body to form a plurality of mesas including first and second mesas having different height dimensions and different numbers of the active layers; and
selectively oxidizing the selected oxide layer of the plurality of mesas from a side surface.
